(19) United States
(12) Patent Application Publication
(10) Pub. No.: US 2024/0355852 A1
(43) Pub. Date: Oct. 24, 2024

(54) PHOTOELECTRIC CONVERSION APPARATUS, PHOTOELECTRIC CONVERSION SYSTEM, AND MOVABLE BODY

(71) Applicant: CANON KABUSHIKI KAISHA, Tokyo (JP)

(72) Inventors: KAZUHIRO MORIMOTO, Kanagawa (JP); JUNJI IWATA, Tokyo (JP); YU MAEHASHI, Hokkaido (JP); HIROSHI SEKINE, Kanagawa (JP)

(21) Appl. No.: 18/758,777

(22) Filed: Jun. 28, 2024

Related U.S. Application Data
(63) Continuation of application No. PCT/JP2022/000071, filed on Jan. 5, 2022.

(51) Int. Cl. H01L 27/146

(52) U.S. Cl. CPC H01L 27/14625; H01L 27/1462; H01L 27/1463; H01L 27/14636; H01L 27/1464; H01L 27/14643

(57) ABSTRACT

A photoelectric conversion apparatus includes a plurality of avalanche diodes disposed in a semiconductor layer including a first surface and a second surface facing the first surface, and a first wiring structure in contact with the second surface, wherein a first pad configured to apply a first voltage to the photoelectric conversion apparatus is disposed in the first wiring structure, wherein the semiconductor layer includes a plurality of uneven structures disposed in the first surface, and wherein an effective pitch of the plurality of uneven structures is smaller than hc/Eₐ where h is a Planck constant [J·s], c is a speed of light [m/s], and Eₐ is a band gap [J] of a substrate.

### CROSS-REFERENCE TO RELATED APPLICATIONS

This application is a Continuation of International Patent Application No. PCT/JP2022/000071, filed Jan. 5, 2022, which is hereby incorporated by reference herein in its entirety.

### BACKGROUND OF THE INVENTION

### Field of the Invention

The present invention relates to a photoelectric conversion apparatus and a photoelectric conversion system.

### Background Art

Some photoelectric conversion apparatuses have an uneven structure in a light-receiving surface of a photoelectric conversion element to refract incident light, whereby the optical path length of the incident light in the photoelectric conversion element is lengthened, which improves the quantum efficiency. Japanese Patent Application Laid-Open No. 2021-002542 (PTL 1) discusses a single-photon avalanche photodiode (SPAD) having an uneven structure termed a moth-eye structure in a portion close to the light incident surface of a substrate.

### CITATION LIST

### Patent Literature

PTL 1: Japanese Patent Application Laid-Open No. 2021-002542

In the structure discussed in PTL 1, however, there is an issue that photons generated by avalanche light emission are reflected from a silicon (Si) back surface of the moth-eye structure, and crosstalk as stray light is induced.

### SUMMARY OF THE INVENTION

In view of the above-described issue, the present invention is directed to reducing crosstalk in a photoelectric conversion apparatus that uses an avalanche photodiode.

According to an aspect of the present invention, a photoelectric conversion apparatus includes a plurality of avalanche diodes disposed in a semiconductor layer including a first surface and a second surface facing the first surface, and a first wiring structure in contact with the second surface, each of the plurality of avalanche diodes including a first semiconductor region of a first conductivity type disposed at a first depth, and a second semiconductor region of a second conductivity type disposed at a second depth deeper than the first depth relative to the second surface, wherein a first pad configured to apply a first voltage to the photoelectric conversion apparatus is disposed in the first wiring structure, wherein the semiconductor layer includes a plurality of uneven structures disposed in the first surface, and wherein an effective pitch of the plurality of uneven structures is smaller than hc/Eₐ where h is a Planck constant [J·s], c is a speed of light [m/s], and Eₐ is a band gap [J] of a substrate.

According to another aspect of the present invention, a photoelectric conversion apparatus includes a plurality of avalanche diodes disposed in a semiconductor layer including a first surface and a second surface facing the first surface, and a first wiring structure in contact with the second surface, each of the plurality of avalanche diodes including a first semiconductor region of a first conductivity type disposed at a first depth, and a second semiconductor region of a second conductivity type disposed at a second depth deeper than the first depth relative to the second surface, wherein a first pad configured to apply a first voltage to the photoelectric conversion apparatus is disposed in the first wiring structure, wherein the semiconductor layer includes a plurality of uneven structures disposed in the first surface, and wherein an effective pitch of the plurality of uneven structures is smaller than 1.1 μm.

Further features of the present invention will become apparent from the following description of exemplary embodiments with reference to the attached drawings.

### BRIEF DESCRIPTION OF THE DRAWINGS

FIG. 1 is a schematic diagram of a photoelectric conversion apparatus according to exemplary embodiments.

FIG. 2 is a schematic diagram of a photodiode (PD) substrate of the photoelectric conversion apparatus according to the exemplary embodiments.

FIG. 3 is a schematic diagram of a circuit substrate of the photoelectric conversion apparatus according to the exemplary embodiments.

FIG. 4 is an example of a configuration of a pixel circuit of the photoelectric conversion apparatus according to the exemplary embodiments.

FIGS. 5A to 5C are schematic diagrams illustrating driving of the pixel circuit of the photoelectric conversion apparatus according to the exemplary embodiments.

FIG. 6 is a cross-sectional view of a photoelectric conversion element according to a first exemplary embodiment.

FIG. 7 is a potential diagram of the photoelectric conversion element according to the first exemplary embodiment.

FIG. 8 is a cross-sectional view of a trench structure according to a first exemplary embodiment.

FIG. 9A is a plan view of the photoelectric conversion element according to the first exemplary embodiment.

FIG. 9B is a plan view of the photoelectric conversion element according to the first exemplary embodiment.

FIG. 10 is a diagram illustrating a comparative example of the photoelectric conversion element according to the first exemplary embodiment.

FIG. 11 is a cross-sectional view of the photoelectric conversion element according to a first exemplary embodiment.

FIG. 12A is a plan view of a photoelectric conversion element according to a second exemplary embodiment.

FIG. 12B is a plan view of the photoelectric conversion element according to the second exemplary embodiment.

FIG. 13A is a plan view of a photoelectric conversion element according to a variation of the second exemplary embodiment.

FIG. 13B is a plan view of a photoelectric conversion element according to a variation of the second exemplary embodiment.

FIG. 14 is a plan view of a photoelectric conversion element according to a third exemplary embodiment.

FIG. 15 is a plan view of the photoelectric conversion element according to the third exemplary embodiment.

FIG. 16 is a cross-sectional view of the photoelectric conversion element according to the third exemplary embodiment.

FIG. 17 is a cross-sectional view of the photoelectric conversion element according to the third exemplary embodiment.

FIG. 18 is a cross-sectional view of a photoelectric conversion element according to a fourth exemplary embodiment.

FIG. 19A is a plan view of the photoelectric conversion element according to the fourth exemplary embodiment.

FIG. 19B is a plan view of the photoelectric conversion element according to the fourth exemplary embodiment.

FIG. 20 is a diagram illustrating a comparative example of the photoelectric conversion element according to the fourth exemplary embodiment.

FIG. 21 is a cross-sectional view of a photoelectric conversion element according to a fifth exemplary embodiment.

FIG. 22A is a cross-sectional view of a trench structure according to a sixth exemplary embodiment.

FIG. 22B is a cross-sectional view of a trench structure according to the sixth exemplary embodiment.

FIG. 22C is a cross-sectional view of a trench structure according to the sixth exemplary embodiment.

FIG. 23 is a cross-sectional view of a photoelectric conversion element according to a seventh exemplary embodiment.

FIG. 24A is a plan view of the photoelectric conversion element according to the seventh exemplary embodiment.

FIG. 24B is a plan view of the photoelectric conversion element according to the seventh exemplary embodiment.

FIG. 25 is a cross-sectional view of a photoelectric conversion element according to an eighth exemplary embodiment.

FIG. 26 is a cross-sectional view of a photoelectric conversion element according to a ninth exemplary embodiment.

FIG. 27 is a cross-sectional view of a photoelectric conversion element according to a tenth exemplary embodiment.

FIG. 28 is a cross-sectional view of a photoelectric conversion element according to an eleventh exemplary embodiment.

FIG. 29 is a cross-sectional view of a photoelectric conversion element according to an eleventh exemplary embodiment.

FIG. 30 is a functional block diagram of a photoelectric conversion system according to a thirteenth exemplary embodiment.

FIG. 31A is a functional block diagram of a photoelectric conversion system according to a fourteenth exemplary embodiment.

FIG. 31B is a functional block diagram of the photoelectric conversion system according to the fourteenth exemplary embodiment.

FIG. 32 is a functional block diagram of a photoelectric conversion system according to a fifteenth exemplary embodiment.

FIG. 33 is a functional block diagram of a photoelectric conversion system according to a sixteenth exemplary embodiment.

FIG. 34A is a diagram of a photoelectric conversion system according to a seventeenth exemplary embodiment.

FIG. 34B is a diagram of a photoelectric conversion system according to a seventeenth exemplary embodiment.

### DESCRIPTION OF THE EMBODIMENTS

Exemplary embodiments described below are intended to embody the technical idea of the present invention, and do not limit the present invention. The size and positional relationship of members shown in each drawing may be exaggerated for the sake of clarity. In the following description, the same components are denoted by the same reference numerals, and the description thereof may be omitted.

Hereinafter, the exemplary embodiments of the present invention will be described in detail with reference to the drawings. In the following description, terms indicating specific directions and positions (for example, “up”, “down”, “right”, “left”, and other terms including these terms) are used as necessary. The use of these terms is for facilitating understanding of the exemplary embodiments with reference to the drawings, and the technical scope of the present invention is not limited by the meanings of these terms.

In the specification, a planar view refers to a view in a direction perpendicular to a light incident surface of a semiconductor layer. A cross-sectional view refers to a view from a surface in a direction perpendicular to the light incident surface. In a case where the light incident surface of the semiconductor layer is a rough surface when viewed microscopically, a planar view is defined based on the light incident surface of the semiconductor layer when viewed macroscopically.

In the following descriptions, the anode of an avalanche photodiode (APD) is at a fixed potential, and a signal is extracted from the cathode side. Thus, a semiconductor region of a first conductivity type in which charges having the same polarity as that of signal charges are majority carriers is an N-type semiconductor region, and a semiconductor region of a second conductivity type in which charges having a polarity different from that of the signal charges are majority carriers is a P-type semiconductor region. Even in a case where the cathode of the APD is at a fixed potential, and a signal is extracted from the anode side, the present invention holds true. In this case, a semiconductor region of the first conductivity type in which charges having the same polarity as that of signal charges are majority carriers is a P-type semiconductor region, and a semiconductor region of the second conductivity type in which charges having a polarity different from that of the signal charges are majority carriers is an N-type semiconductor region. While a description is given below of a case where one of the nodes of the APD is at a fixed potential, the potentials of both nodes may be variable.

In this specification, the term “impurity concentration” means a net impurity concentration obtained by subtracting compensation by impurities of the opposite conductivity type. That is, an “impurity concentration” refers to a net doping concentration. A region where a P-type additive impurity concentration is higher than an N-type additive impurity concentration is a P-type semiconductor region. Conversely, a region where an N-type additive impurity concentration is higher than a P-type additive impurity concentration is an N-type semiconductor region.

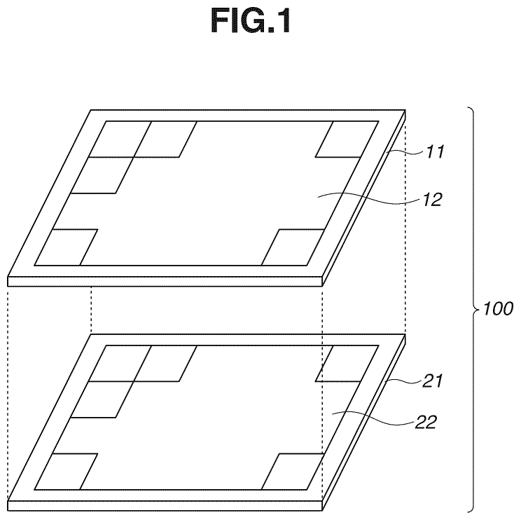

With reference to FIG. 1 to FIGS. 5A to 5C, descriptions are given of configurations common to exemplary embodiments of a photoelectric conversion apparatus and a method for driving the photoelectric conversion apparatus according to the present invention.

FIG. 1 is a diagram illustrating the configuration of a multilayer type photoelectric conversion apparatus 100 according to the exemplary embodiments of the present invention. In the photoelectric conversion apparatus 100, two substrates, namely a sensor substrate 11 and a circuit substrate 21, are stacked and electrically connected. The sensor substrate 11 includes a first semiconductor layer including photoelectric conversion elements 102, and a first wiring structure. The circuit substrate 21 includes a second semiconductor layer including circuits, such as signal processing units 103, and a second wiring structure. The photoelectric conversion apparatus 100 includes the second semiconductor layer, the second wiring structure, the first wiring structure, and the first semiconductor layer which are stacked in this order. The photoelectric conversion apparatus 100 according to the exemplary embodiments is a back-side illumination photoelectric conversion apparatus in which light is incident on a first surface and a circuit substrate is disposed on a second surface.

The sensor substrate 11 and the circuit substrate 21 are described below as diced chips, but are not limited to chips. For example, each of the sensor substrate 11 and the circuit substrate 21 may be a wafer. The sensor substrate 11 and the circuit substrate 21 may be stacked in wafer states and then diced, or the sensor substrate 11 and the circuit substrate 21 may be chipped, and then, the chips may be stacked and joined together.

In the sensor substrate 11, a pixel region 12 is disposed. In the circuit substrate 21, a circuit area 22 that processes a signal detected in the pixel region 12 is disposed.

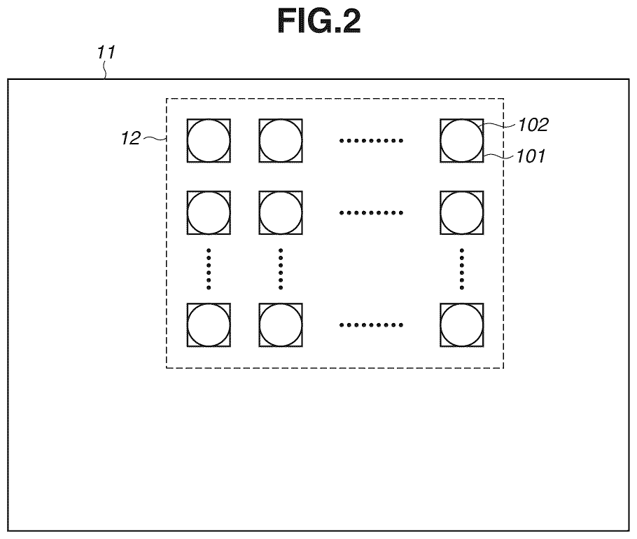

FIG. 2 illustrates an example of the arrangement of the sensor substrate 11. Pixels 101 each having a photoelectric conversion element 102 including an avalanche photodiode (hereinafter, “APD”) are arranged in a two-dimensional array in a planar view and forms the pixel region 12.

A typical example of the pixels 101 is a pixel for forming an image. In a case where the pixels 101 are used in time of flight (ToF), the pixels 101 may not necessarily form an image. That is, the pixels 101 may also be an elements for measuring a time when light reaches the pixel 101, and the amount of the light.

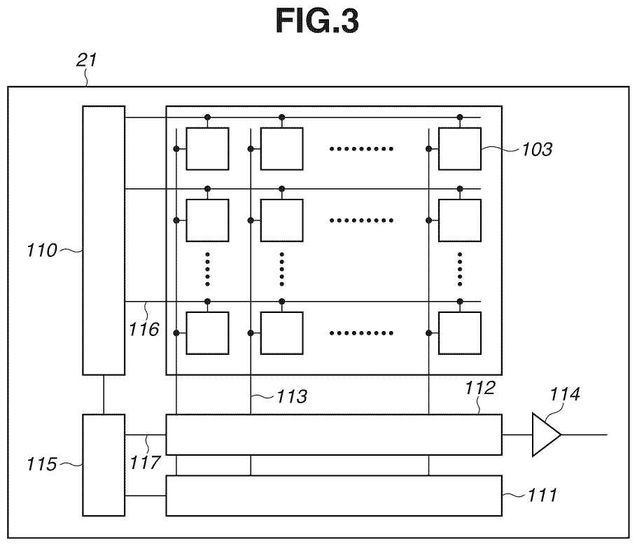

FIG. 3 is a diagram illustrating the configuration of the circuit substrate 21. The circuit substrate 21 includes the signal processing units 103 that process charges photoelectrically converted by the photoelectric conversion elements 102 in FIG. 2, a column circuit 112, a control pulse generation unit 115, a horizontal scanning circuit unit 111, signal lines 113, and a vertical scanning circuit unit 110.

The photoelectric conversion elements 102 in FIG. 2 and the signal processing units 103 in FIG. 3 are electrically connected together via connection wires disposed for the respective pixels 101.

The vertical scanning circuit unit 110 receives a control pulse supplied from the control pulse generation unit 115 and supplies the control pulse to the pixels 101. As the vertical scanning circuit unit 110, a logic circuit, such as a shift register or an address decoder, is used.

Signals output from the photoelectric conversion elements 102 of the pixels 101 are processed by the signal processing units 103. The signal processing units 103 each include a counter and a memory. The memory stores a digital value therein.

In reading of signals from memories of the pixels 101 holding digital signals, the horizontal scanning circuit unit 111 inputs control pulses to the signal processing units 103 to sequentially select columns.

In a selected column, signals are output to the signal line 113 from signal processing units 103 of pixels 101 selected by the vertical scanning circuit unit 110.

The signals output to the signal lines 113 are output to a recording unit or a signal processing unit outside the photoelectric conversion apparatus 100 via an output circuit 114.

In FIG. 2, the photoelectric conversion elements 102 in the pixel region 12 may be arranged in one-dimensional form. Even in a case where only a single pixel 101 is disposed, the effects of the present invention can be obtained, and a case where only a single pixel 101 is disposed is also included in the present invention. The function of the signal processing unit 103 do not need to be included in each photoelectric conversion element 102, and for example, a single signal processing unit 103 may be shared by a plurality of photoelectric conversion elements 102 and sequentially perform signal processing.

As illustrated in FIGS. 2 and 3, the plurality of signal processing units 103 is disposed in an area overlapping the pixel region 12 in the planar view. The vertical scanning circuit unit 110, the horizontal scanning circuit unit 111, the column circuit 112, the output circuit 114, and the control pulse generation unit 115 are disposed in an overlapping manner between the ends of the sensor substrate 11 and the ends of the pixel region 12 in the planar view. In other words, the sensor substrate 11 includes the pixel region 12 and a non-pixel region disposed around the pixel region 12, and the vertical scanning circuit unit 110, the horizontal scanning circuit unit 111, the column circuit 112, the output circuit 114, and the control pulse generation unit 115 are disposed in an area overlapping the non-pixel region in the planar view.

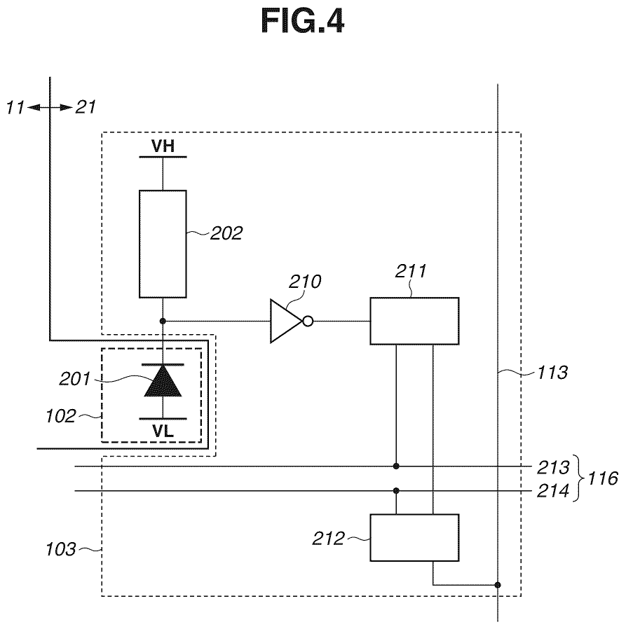

FIG. 4 is an example of a block diagram including an equivalent circuit of each pixel 101 in FIGS. 2 and 3.

In FIG. 4, the photoelectric conversion element 102 including an APD 201 is disposed in the sensor substrate 11, and other members are disposed in the circuit substrate 21.

The APD 201 generates a charge pair according to incident light through photoelectric conversion. To the anode of the APD 201, a voltage VL (a first voltage) is supplied. To the cathode of the APD 201, a voltage VH (a second voltage) higher than the voltage VL supplied to the anode is supplied. To the anode and the cathode of the APD 201, reverse bias voltages that cause the APD 201 to perform an avalanche multiplication operation are supplied. By bringing the APD 201 into a state in which such voltages are supplied, the charges generated by the incident light cause avalanche multiplication, and an avalanche current is generated.

In a state in which reverse bias voltages are supplied, APDs are operated in Geiger mode or Linear mode. In Geiger mode, APDs are operated with an anode-cathode potential difference larger than the breakdown voltage. In Linear mode, APDs are operated with an anode-cathode potential difference near the breakdown voltage or smaller than or equal to the breakdown voltage.

An APD that is operated in Geiger mode is referred to as a single-photon avalanche diode (SPAD). For example, the voltage VL (first voltage) is −30 V, and the voltage VH (second voltage) is 1 V. The APD 201 may be operated in Linear mode or may operated in Geiger mode. In the case of an SPAD, the potential difference of an APD is greater than that of an APD operating in Linear mode, which has a significant effect on pressure resistance. Thus, it is desirable that the APD 201 be an SPAD.

A quench element 202 is connected to the APD 201 and a power supply that supplies the voltage VH. The quench element 202 functions as a load circuit (a quench circuit) when a signal is multiplied by avalanche multiplication, and has a function of suppressing avalanche multiplication by reducing a voltage to be supplied to the APD 201 (quench operation). The quench element 202 also has a function of returning a voltage supplied to the APD 201 to the voltage VH (recharge operation) by applying a current corresponding to the voltage dropped by the quench operation.

The signal processing unit 103 includes a waveform shaping unit 210, a counter circuit 211, and a selection circuit 212. In this specification, a configuration of the signal processing unit 103 is not limited as long as the signal processing unit 103 includes any of the waveform shaping unit 210, the counter circuit 211, and the selection circuit 212.

The waveform shaping unit 210 shapes a change in the potential of the cathode of the APD 201 obtained at the time of photon detection, and outputs a pulse signal. As the waveform shaping unit 210, for example, an inverter circuit is used. While FIG. 4 illustrates an example in which a single inverter is used as the waveform shaping unit 210 in, a circuit in which a plurality of inverters is connected in series may be used, or another circuit having a waveform shaping effect may be used.

The counter circuit 211 counts pulse signals output from the waveform shaping unit 210 and stores the count value. In response to a control pulse pRES being supplied to the counter circuit 211 via a driving line 213, the count value of the pulse signals held in the counter circuit 211 is reset.

A control pulse pSEL is supplied to the selection circuit 212 from the vertical scanning circuit unit 110 in FIG. 3 via a driving line 214 in FIG. 4 (not illustrated in FIG. 3), and electrical connection or disconnection between the counter circuit 211 and the signal line 113 is switched. The selection circuit 212 includes a buffer circuit for outputting a signal, for example.

Electric connection may be switched with a switch, such as a transistor, disposed between the quench element 202 and the APD 201 or between the photoelectric conversion element 102 and the signal processing unit 103. Similarly, the supply of the voltage VH or the voltage VL to the photoelectric conversion element 102 may be electrically switched with a switch, such as a transistor.

In the present exemplary embodiment, a configuration that uses the counter circuit 211 has been described. Alternatively, the photoelectric conversion apparatus 100 may acquire the pulse detection timing by using a time-to-digital conversion circuit (a time-to-digital converter: hereinafter, a TDC) and a memory instead of the counter circuit 211. In this case, the generation timing of a pulse signal output from the waveform shaping unit 210 is converted into a digital signal by the TDC. To measure the timing of a pulse signal, a control pulse pREF (reference signal) is supplied to the TDC from the vertical scanning circuit unit 110 in FIG. 3 via a driving line. The TDC uses the control pulse pREF as a reference to acquire, as a digital signal, a signal by using a timing when the input timing of a signal output from each pixel 101 via the waveform shaping unit 210 as a relative time.

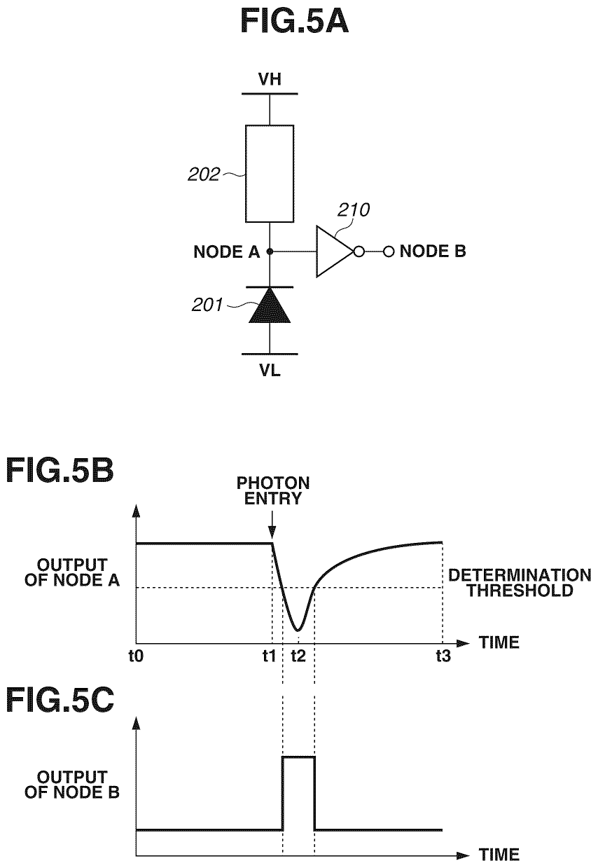

FIGS. 5A to 5C are diagrams schematically illustrating the relationship between an operation of the APD 201 and an output signal.

FIG. 5A is a diagram illustrating the APD 201, the quench element 202, and the waveform shaping unit 210 in FIG. 4. The input side of the waveform shaping unit 210 is a node A, and the output side of the waveform shaping unit 210 is a node B. FIG. 5B illustrates a waveform change in the node A in FIG. 5A. FIG. 5C illustrates a waveform change in the node B in FIG. 5A.

During a period from a time t0 and a time t1, a potential difference of VH-VL is applied to the APD 201 in FIG. 5A. At the time t1, upon entry of a photon to the APD 201, avalanche multiplication occurs in the APD 201, an avalanche multiplication current flows through the quench element 202, and the voltage of the node A drops. With further increase in the voltage drop and decrease in the potential difference applied to the APD 201, then at a time t2 as illustrated in FIG. 5B, the avalanche multiplication in the APD 201 stops, whereby dropping of the voltage level of the node A stops at a certain value. Then, during a period between the time t2 and a time t3, a current that compensating the voltage drop from the voltage VL flows through the node A, and at the time t3, the potential level of the node A is static at the original potential level. At this time, a portion of the output waveform of the node A exceeding a certain threshold is waveform-shaped by the waveform shaping unit 210, and output as a signal from the node B.

The arrangement of the signal lines 113 and the arrangement of the column circuit 112 and the output circuit 114 are not limited to those in FIG. 3. For example, the signal lines 113 may be extended in the row direction, and the column circuit 112 may be disposed at the extension ends of the signal lines 113.

The photoelectric conversion apparatus 100 according to each of the exemplary embodiments is described below.

### First Exemplary Embodiment

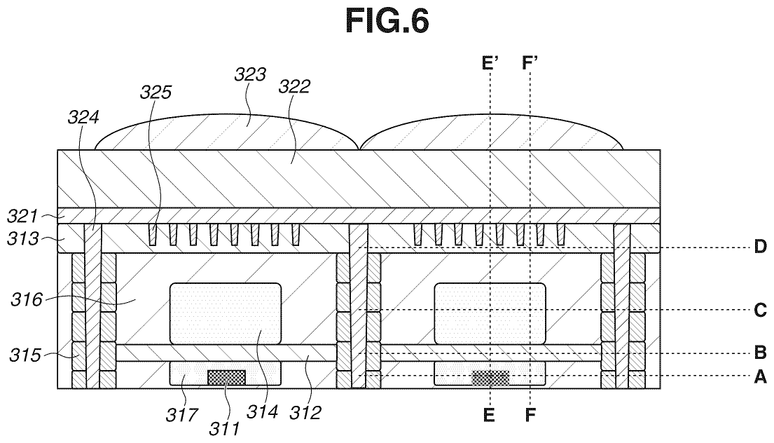

With reference to FIGS. 6 to 11, a photoelectric conversion apparatus 100 according to a first exemplary embodiment is described.

FIG. 6 is a cross-sectional view of the photoelectric conversion elements 102 of two pixels 101 of the photoelectric conversion apparatus 100 according to the present exemplary embodiment in a direction perpendicular to the surface direction of the substrates 11 and 21.

The structure and the function of each photoelectric conversion element 102 are described. The photoelectric conversion element 102 includes a first semiconductor region 311, a fourth semiconductor region 314, a sixth semiconductor region 316, and a seventh semiconductor region 317 which are of an N-type. The photoelectric conversion element 102 further includes a second semiconductor region 312, a third semiconductor region 313, and a fifth semiconductor region 315 which are of a P-type.

In the present exemplary embodiment, in the cross section illustrated in FIG. 6, the first semiconductor region 311 of the N-type is formed near a surface facing a light incident surface, and the seventh semiconductor region 317 of the N-type is formed around the first semiconductor region 311. The second semiconductor region 312 of the P-type is formed at a position overlapping the first semiconductor region 311 and the third semiconductor region 313 in a planar view. The fourth semiconductor region 314 of the N-type is further disposed at a position overlapping the second semiconductor region 312 in the planar view, and the sixth semiconductor region 316 of the N-type is formed around the fourth semiconductor region 315.

The N-type impurity concentration of the first semiconductor region 311 is higher than those of the fourth semiconductor region 314 and the seventh semiconductor region 317. Between the second semiconductor region 312 of the P-type and the first semiconductor region 311 of the N-type, a P-N junction is formed. Setting the impurity concentration of the second semiconductor region 312 to be lower than the impurity concentration of the first semiconductor region 311 causes the entire region of the second semiconductor region 312 to be a depletion layer region. Further, the depletion layer region extends to a partial region of the first semiconductor region 311, and an intense electric field is induced in the extended depletion layer region. This intense electric field causes avalanche multiplication in the depletion layer region extended to the partial region of the first semiconductor region 311, and a current based on amplified charges is output as signal charges. In response to light incident on the photoelectric conversion element 102 being photoelectrically converted and avalanche multiplication occurring in the depletion layer region (avalanche multiplication region), generated charges of a first conductivity type are collected in the first semiconductor region 311.

Although the fourth semiconductor region 314 and the seventh semiconductor region 317 are formed in comparable sizes in FIG. 6, the sizes of the semiconductor regions 314 and 317 are not limited to these. For example, the fourth semiconductor region 314 may be formed to be larger than the seventh semiconductor region 317, and charges may be collected in the first semiconductor region 311 from a wider range.

In the first semiconductor layer surface close to the light incident surface, an uneven structure 325 with trenches is formed. The uneven structure 325 is surrounded by the third semiconductor region 313 of the P-type and scatters light incident on the photoelectric conversion element 102. Since the incident light obliquely travels in the photoelectric conversion element 102, an optical path length is greater than or equal to the thickness of the first semiconductor layer. This leads to photoelectrical conversion of light having a wavelength longer than a wavelength of a case where the uneven structure 325 is not included. Further, the uneven structure 325 prevents the incident light from being reflected in the sensor substrate 11, and therefore, the effect of improving the photoelectric conversion efficiency of the incident light is obtained.

The fourth semiconductor region 314 and the uneven structure 325 are formed to overlap each other in the planar view. The area of the overlap between the fourth semiconductor region 314 and the uneven structure 325 in the planar view is greater than the area of a portion of the fourth semiconductor region 314 that does not overlap the uneven structure 325. The movement time of a charge generated at a position far from an avalanche multiplication region formed between the first semiconductor region 311 and the fourth semiconductor region 314 until the charge reaches the avalanche multiplication region is longer than the movement time of a charge generated at a position close to the avalanche multiplication region until the charge reaches the avalanche multiplication region. Thus, timing jitter may be increased. With the configuration in which the fourth semiconductor region 314 and the uneven structure 325 are disposed at the position where the fourth semiconductor region 314 and the uneven structure 325 overlap each other in the planar view, an electric field in a deep portion of the photodiode is increased and the collection time of charges generated at a position far from the avalanche multiplication region is shortened, whereby the timing jitter is reduced.

Further, the third semiconductor region 313 three-dimensionally covers the uneven structure 325, whereby generation of a thermal excitation charge in an interface portion of the uneven structure 325 is prevented. This reduces the Dark Count Rate (DCR) of the photoelectric conversion element 102.

The pixels 101 are separated from each other by a pixel separation portion 324 having a trench structure, and the fifth semiconductor region 315 of the P-type formed around the pixel separation portion 324 separates the photoelectric conversion elements 102 adjacent to each other by a potential barrier. Since the photoelectric conversion elements 102 are separated from each other also based on the potential of the fifth semiconductor region 315, a trench structure such as the pixel separation portion 324 is not essential as a pixel separation portion. Even in a case where the pixel separation portion 324 is disposed, the depth and the position of the pixel separation portion 324 are not limited to the configuration illustrated in FIG. 6. The pixel separation portion 324 may be deep trench isolation (DTI) penetrating the first semiconductor layer, or may be DTI that does not penetrate the first semiconductor layer. The light blocking performance may be improved by embedding metal in DTI. The pixel separation portion 324 may be configured to surround the entire periphery of the photoelectric conversion element 102 in the planar view, or for example, may be configured only in opposite side portions of the photoelectric conversion element 102.

The distance from the pixel separation portion 324 to the pixel separation portion 324 of an adjacent pixel 101 or a pixel 101 disposed at the closest position can also be regarded as the size of a single photoelectric conversion element 102. In a case where, for example, a second avalanche diode is disposed between a first avalanche diode and a third avalanche diode, a first pixel separation portion is between the first and second avalanche diodes, and a second pixel separation portion is between the second and third avalanche diodes. The distance between the first and second pixel separation portions can also be referred to as the size of a single piece of the photoelectric conversion element 102.

A distance d from the light incident surface to an avalanche multiplication region satisfies L√2/4<d<L×√2, where the size of a single photoelectric conversion element 102 is L. With the size and the depth of the photoelectric conversion element 102 satisfying this relational expression, the intensity of an electric field in the depth direction and the intensity of an electric field in the planar direction near the first semiconductor region 311 are comparable with each other. Consequently, variations in the time taken to collect charges is reduced, whereby occurrence of the timing jitter is reduced.

On the first semiconductor layer on the light incident surface side, a pinning layer 321, a planarization layer 322, and a microlens 323 are further formed. On the first semiconductor layer on the light incident surface side, a filter layer (not illustrated) may be further disposed. As the filter layer, various optical filters, such as a color filter, an infrared cut filter, and a monochrome filter can be used. As the color filter, a red, green, and blue (RGB) color filter or a red, green, blue, and white (RGBW) color filter can be used.

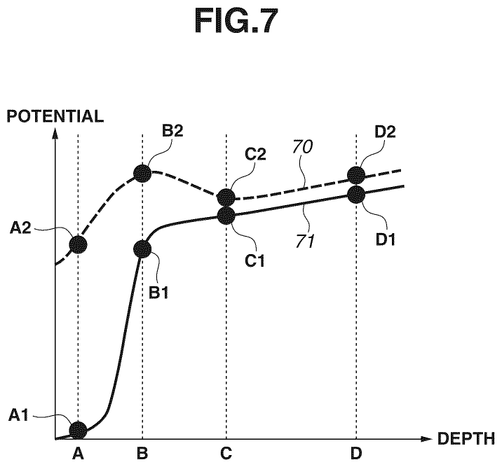

FIG. 7 is a potential diagram of each photoelectric conversion element 102 illustrated in FIG. 6.

A dotted line 70 in FIG. 7 indicates the potential distribution of a line segment FF′ in FIG. 6. A solid line 71 in FIG. 7 indicates the potential distribution of a line segment EE′ in FIG. 6. FIG. 7 illustrates the potentials in terms of electrons as main carrier charges in an N-type semiconductor region. In a case where main carrier charges are holes, the potential level relationship is reversed. A depth A (first depth) in FIG. 7 corresponds to a height A in FIG. 6. Similarly, a depth B (third depth) corresponds to a height B, a depth C corresponds to a height C, and a depth D (second depth) corresponds to a height D.

In FIG. 7, at the depth A, the solid line 71 indicates a potential level A1, and the dotted line 70 indicates a potential level A2. At the depth B, the solid line 71 indicates a potential level B1, and the dotted line 70 indicates a potential level B2. At the depth C, the solid line 71 indicates a potential level C1, and the dotted line 70 indicates a potential level C2. At the depth D, the solid line 71 indicates a potential level D1, and the dotted line 70 indicates a potential level D2.

Based on FIGS. 6 and 7, the potential level of the first semiconductor region 311 corresponds to the potential level A1, and the potential level near a center portion of the second semiconductor region 312 corresponds to the potential level B1. The potential level of the seventh semiconductor region 317 corresponds to the potential level A2, and the potential level of an outer edge portion of the second semiconductor region 312 corresponds to the potential level B2.

In the dotted line 70 in FIG. 7, the potential gradually decreases from the depth D to the depth C. Then, the potential gradually increases from the depth C to the depth B and reaches the level B2 at the depth B. Further, the potential decreases from the depth B to the depth A and reaches the level A2 at the depth A.

On the other hand, in the solid line 71, the potential gradually decreases from the depth D to the depth C and from the depth C to the depth B and reaches the level B1 at the depth B. Then, the potential steeply decreases from the depth B to the depth A and reaches the level A1 at the depth A. At the depth D, the potentials indicated by the dotted lines 70 and 71 are at almost the same levels and have potential gradients that gradually decrease toward the second surface of the first semiconductor layer in regions indicated by the line segments EE′ and FF′. Thus, charges generated in an optical detection apparatus move toward the second surface due to the gradual potential gradients.

In an avalanche diode according to the present exemplary embodiment, the impurity concentration of the second semiconductor region 312 of the P-type is lower than that of the first semiconductor region 311 of the N-type, and potentials reverse-biased with respect to each other are supplied to the first semiconductor region 311 and the second semiconductor region 312. Consequently, a depletion layer region is formed in a portion near the second semiconductor region 312. With this structure, the second semiconductor region 312 serves as a potential barrier against charges photoelectrically converted in the fourth semiconductor region 314, whereby charges are likely to be collected in the first semiconductor region 311.

While the second semiconductor region 312 is formed on the entire surface of the photoelectric conversion element 102 in FIG. 6, for example, the second semiconductor region 312 may not be disposed and a slit in which the fourth semiconductor region 314 extends may be formed in a portion that overlaps the first semiconductor region 311 in the planar view. In this case, due to the potential difference between the second semiconductor region 312 and the slit portion, the potential decreases in a direction from the line segment FF′ to the line segment EE′ at the depth C in FIG. 6. Consequently, during the process in which charges photoelectrically converted in the fourth semiconductor region 314 move, the charges are likely to move in the direction of the first semiconductor region 311. On the other hand, in a case where the second semiconductor region 312 is formed on the entire surface as illustrated in FIG. 6, a voltage that is applied to obtain an intense electric field causing avalanche multiplication can be set lower than a voltage of a case where the slit is formed. This reduces noise due to the formation of a local intense electric field region.

Charges having moved to a portion around the second semiconductor region 312 are accelerated by the steep potential gradient from the depth B to the depth A in the solid line 71 in FIG. 7, i.e., an intense electric field, whereby avalanche multiplication occurs.

In contrast, in the potential distribution between the seventh semiconductor region 317 and the second semiconductor region 312 of the P-type in FIG. 6, i.e., from the depth B to the depth A in the dotted line 70 in FIG. 7, avalanche multiplication does not occur. Thus, without increasing the area of an intense electric field region (avalanche multiplication region) relative to the size of the photodiode, charges generated in the fourth semiconductor region 314 are counted as signal charges. While, in the above description, the conductivity type of the seventh semiconductor region 317 is the N-type, the seventh semiconductor region 317 may be a semiconductor region of the P-type as long as the seventh semiconductor region 317 has a concentration satisfying the above potential relationship.

Charges photoelectrically converted in the second semiconductor region 312 flow into the fourth semiconductor region 314 due to the potential gradient from the depth B to the depth C in the dotted line 70 in FIG. 7. In this structure, charges in the fourth semiconductor region 314 are likely to move toward the second semiconductor region 312 for the above-described reason. Thus, the charges photoelectrically converted in the second semiconductor region 312 move to the first semiconductor region 311 and are detected as signal charges generated by avalanche multiplication. Thus, the first semiconductor region 311 has sensitivity to the charges photoelectrically converted in the second semiconductor region 312.

The dotted line 70 in FIG. 7 indicates the potential in a cross section along the line segment FF′ in FIG. 6. In the dotted line 70, a portion where the height A and the line segment FF′ meet each other in FIG. 6 is a potential A2, a portion where the height B and the line segment FF′ meet each other in FIG. 6 is a potential B2, a portion where the height C and the line segment FF′ meet each other in FIG. 6 is a potential C2, and a portion where the height D and the line segment FF′ meet each other in FIG. 6 is a potential D2.

Electrons photoelectrically converted in the fourth semiconductor region 314 in FIG. 6 move from the potential D2 to the potential C2 in FIG. 7, but a potential barrier is formed against the electrons from the potential C2 to the potential B2. Thus, the electrons cannot go beyond the potential barrier. Thus, the electrons move to a portion near the center indicated by the line segment EE′ in the fourth semiconductor region 314 in FIG. 6. The electrons having moved to the portion move from the potential C1 to the potential B1 in the potential gradient in FIG. 7 are avalanche-multiplied due to the steep potential gradient from the potential B1 to the potential A1. The electrons pass through the first semiconductor region 311 and then are detected as signal charges.

Charges generated near the boundary between the third semiconductor region 313 and the sixth semiconductor region 316 in FIG. 6 move along the potential gradient from the potential B2 to the potential C2 in FIG. 7. Then, as described above, the charges move to a portion near the center indicated by the line segment EE′ in the fourth semiconductor region 314 in FIG. 6. Then, the charges are avalanche-multiplied due to the steep potential gradient from the potential B1 to the potential A1. The avalanche-multiplied charges pass through the first semiconductor region 311 and then are detected as signal charges.

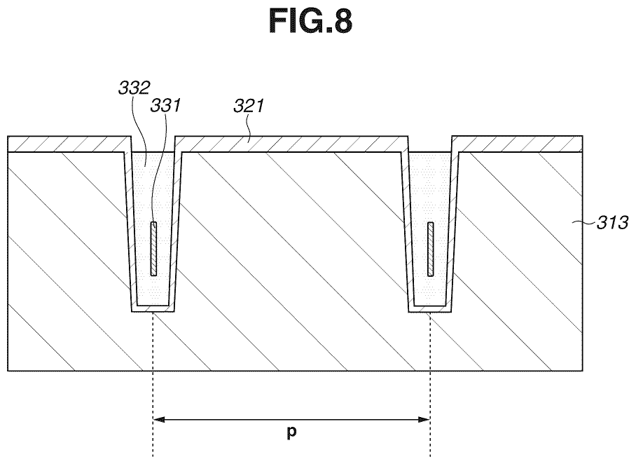

FIG. 8 is an enlarged cross-sectional view of two of the trenches of the uneven structure 325 in the photoelectric conversion apparatus 100 according to the present exemplary embodiment.

This trench structure includes a material different from that of the third semiconductor region 313. For example, in a case where the third semiconductor region 313 is silicon, the main member included in the trench structure is a silicon dioxide film or a silicon nitride film, but a metal or an organic material may be included in the trench structure. For example, each trench is formed at a depth of 0.1 μm to 0.6 μm from the surface of the first semiconductor layer. To sufficiently increase the diffraction of incident light, it is desirable that the depth of the trench be greater than the width of the trench.

The width of the trench is the width from an interface between the pinning layer 321 and the third semiconductor region 313 to an interface between the pinning layer 321 and the third semiconductor region 313 on a plane passing through a center-of-gravity portion of a cross section of the trench. The depth of the trench is the depth from the light incident surface to a bottom of the trench.

A pitch p indicated by an arrow in FIG. 8 indicates a single pitch of the uneven structure 325 including the plurality of trenches. The distance from the center of gravity of one of the trenches of the uneven structure 325 to the center of gravity of another trench adjacent to the trench in the cross-sectional view is the pitch of the uneven structure 325, and an average of the pitches of the trenches of the entirety of the uneven structure 325 is the effective pitch of the uneven structure 325.

The process of forming each trench is described. First, a groove is formed in the third semiconductor region 313 of the first semiconductor layer by etching. Then, the pinning layer 321 is formed on the surface of the third semiconductor region 313 and inside the trench by a method such as a chemical vapor deposition method. The inside of the trench covered by the pinning layer 321 is filled with a filling member 332. The trench of the uneven structure 325 can be filled by the same process as the trench included in the pixel separation portion 324. In this case, a side wall portion of the trench of the uneven structure 325 and a side wall portion of the trench included in the pixel separation portion 324 have comparable impurity concentrations.

The filling member 332 may have a gap 331 inside. Since the refractive index of the gap 331 is lower than the refractive index of the filling member 332, an optical path difference occurs between light passing through the gap 331 and light passing through a part other than the gap 331. The refractive index difference of the whole of the uneven structure 325 is increased and a phase difference that occurs in light passing through the uneven structure 325 is also increased in comparison with a case where the gap 331 is not disposed in the filling member 332. This allows the diffraction of incident light to be easily increased. That is, with a gap disposed in a filling member, the intensity of incident light increases in a particular phase, which results in the effect of improving sensitivity.

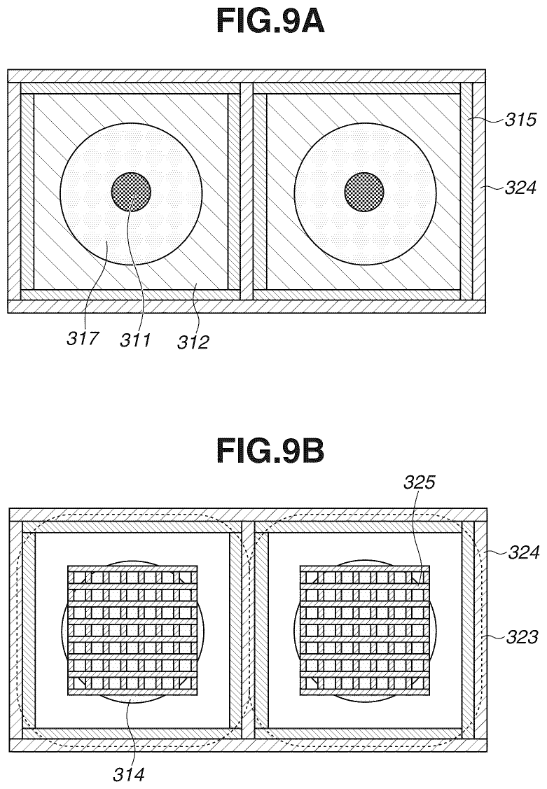

FIGS. 9A and 9B are pixel plan views of the two pixels 101 of the photoelectric conversion apparatus 100 according to the present exemplary embodiment. FIG. 9A is a plan view in a planar view from the surface facing opposite to the light incident surface. FIG. 9B is a plan view in a planar view from the light incident surface.

In FIG. 9A, the first semiconductor region 311, the fourth semiconductor region 314, and the seventh semiconductor region 317 have circular shapes and are disposed in concentric circles. This structure has the effect of preventing local electric field concentration in an end portion of an intense electric field region between the first semiconductor region 311 and the second semiconductor region 312 and reducing the DCR. The shapes of the semiconductor regions are not limited to circular shapes, and for example, may be polygonal shapes having the same position of the center of gravity.

In FIG. 9B, the uneven structure 325 is formed in a grid in the planar view. The uneven structure 325 is formed overlapping the first semiconductor region 311 and the fourth semiconductor region 314, and the position of the center of gravity of the uneven structure 325 is included in the avalanche multiplication region in the planar view. In a trench structure in a grid as illustrated in FIG. 9B, the trench depth in a portion where trenches intersect each other is deeper than the trench depth in a portion where a trench extends alone. However, a bottom portion of each trench in the portion where the trenches intersect each other is at a position closer to the light incident surface than half the thickness of the first semiconductor layer. The state where the trenches intersect each other refers to the state where a recessed portion extending in a first direction and a recessed portion extending in a second direction in the uneven structure 325 intersect each other. The trench depth is the depth from the second surface to the bottom, and can also be referred to as the depth of each recessed portion of the uneven structure 325.

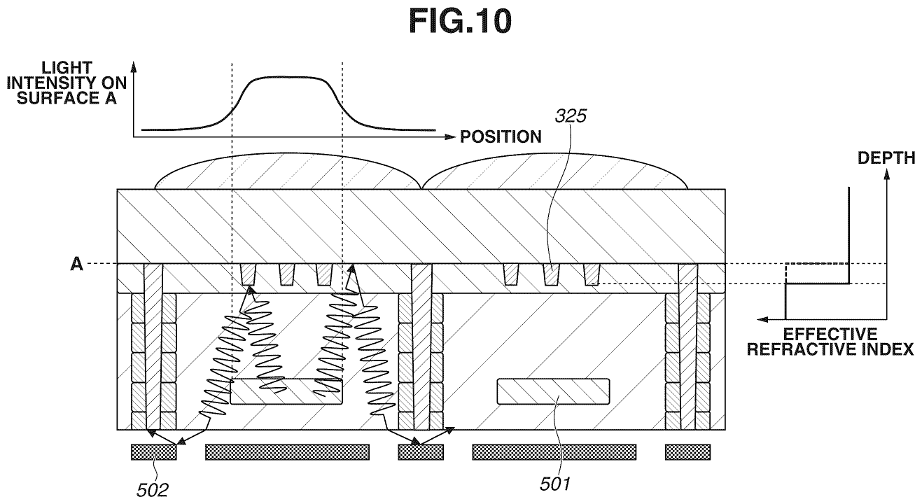

FIG. 10 illustrates a comparative example of the photoelectric conversion apparatus 100 according to the present exemplary embodiment. FIG. 10 illustrates the photoelectric conversion apparatus 100 in a simplified manner. The photoelectric conversion apparatus 100 is a photoelectric conversion apparatus including an avalanche multiplication region 501, a wiring layer 502, and the uneven structure 325.

When light is incident on the photoelectric conversion element 102 having the configuration illustrated in FIG. 10, avalanche light emission may occur in the avalanche multiplication region 501. The avalanche light emission is a phenomenon where photons are generated by the recombination of a large number of electrons or holes generated by avalanche multiplication and charges of a different polarity. The photons generated by the avalanche light emission leak into an adjacent pixel 101, and false signals are generated, which leads to a decrease in image quality.

In the photoelectric conversion element 102 illustrated in FIG. 10, the effective pitch of the uneven structure 325 formed in a portion close to the light incident surface in the first semiconductor layer is greater than the avalanche light emission wavelength. The spectrum of the avalanche light emission light has a certain degree of broadening from a short wavelength to a long wavelength. However, the absorption length of a short-wavelength component is short in the sensor substrate 11, and the short-wavelength component is photoelectrically converted at a position close to a light emission region.

Thus, there is a low probability that the short-wavelength component reaches an adjacent pixel 101 and causes false signals. On the other hand, the absorption length of a long-wavelength component is long in the sensor substrate 11, and there is a high probability that the long-wavelength component causes generation of false signals at a position further from the light emission region. Thus, the long-wavelength component is a dominant factor for a decrease in image quality. Consequently, the component having the maximum wavelength in the spectrum of the avalanche light emission light can be approximately regarded as a representative factor for the decrease in image quality. The maximum value of the wavelength of the avalanche light emission is determined based on the band gap of the material of the substrate and obtained by hc/Eₐ where h is the Planck constant [J·s], c is the speed of light [m/s], and Eₐ is the band gap [J] of the substrate. For example, in a case where the sensor substrate 11 is silicon, the maximum value of the wavelength of the avalanche light emission light is about 1.1 m.

In a case where the effective pitch of the uneven structure 325 is greater than the avalanche light emission wavelength, the avalanche light emission light behaves in a particle-like manner with respect to the uneven structure 325. A change in the effective refractive index relative to the depth of the sensor substrate 11 is steep, and therefore, the avalanche light emission light is reflected from a bottom portion of the uneven structure 325, and the reflected light becomes stray light in the pixel 101.

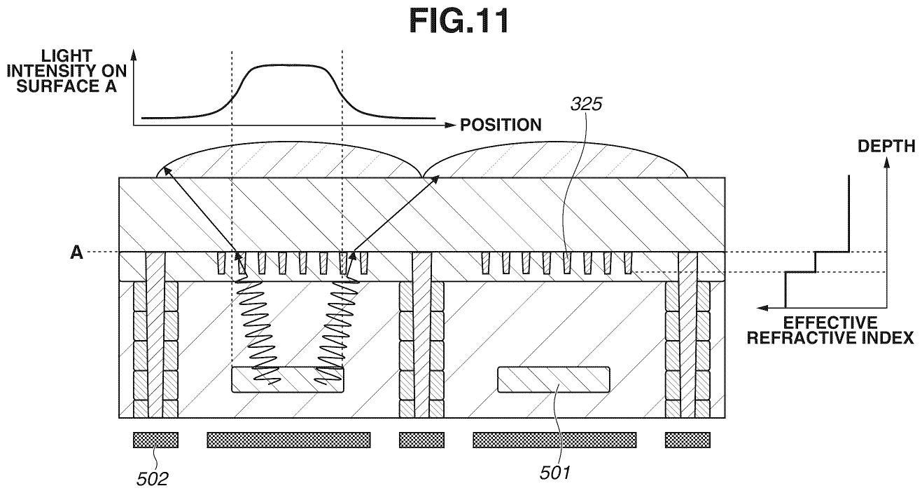

FIG. 11 illustrates an example of the photoelectric conversion apparatus 100 according to the present exemplary embodiment. FIG. 11 also illustrates the photoelectric conversion apparatus 100 in a simplified manner similarly to FIG. 10.

In a photoelectric conversion element 102 illustrated in FIG. 11, the pitch of the uneven structure 325 formed in the portion close to the light incident surface in the first semiconductor layer is smaller than the avalanche light emission wavelength. In a case where the sensor substrate 11 is silicon, the uneven structure 325 is formed at a pitch of 1.1 μm to 0.2 km. In a case where avalanche light emission occurs in the photoelectric conversion element 102 having the configuration illustrated in FIG. 11, the avalanche light emission light behaves in a wave-like manner. A change in the effective refractive index relative to the depth of the first semiconductor layer is gradual, and therefore, the reflection of the avalanche light emission light from a bottom portion of the uneven structure 325 is small, and the avalanche light emission light incident on the uneven structure 325 travels to outside the sensor substrate 11. Thus, stray light in the pixel 101 is reduced. In this configuration, the uneven structure 325 is disposed in a center portion of the photoelectric conversion element 102 where the light intensity of the avalanche light emission light is high on the light incident surface in the first semiconductor layer, whereby the effect of reducing stray light is obtained more efficiently.

Each of the trenches of the uneven structure 325 exemplified in FIG. 11 is in a tapering shape, and does not have a uniform width. In this uneven structure 325, the effects of the present invention is obtainable as long as the condition that the pitch of the uneven structure 325 is smaller than the avalanche light emission wavelength at an average width in a cross-sectional structure (width at a depth half the depth of each trench in FIG. 11) is satisfied. In other words, the width of the trench satisfies hc/2Eₐ where h is the Planck constant [J·s], c is the speed of light [m/s], and Eₐ is the band gap [J] of the substrate, and for example, in a case where the sensor substrate 11 is silicon, the width of the trench is 0.55 μm or less. It can also be said that the effective pitch is smaller than the wavelength at which the light absorption length of the semiconductor substrate and the distance from the light incident surface to an interface between the first semiconductor region 311 and the second semiconductor region 312 are equal to each other.

The wiring layer 502 includes an aluminum (Al) wire and functions as a reflection member that reflects light passing through the first semiconductor layer into the pixel 101.

As described above, the pitch of the uneven structure in the portion close to the light incident surface in the first semiconductor layer is smaller than the avalanche light emission wavelength, whereby crosstalk is reduced.

### Second Exemplary Embodiment

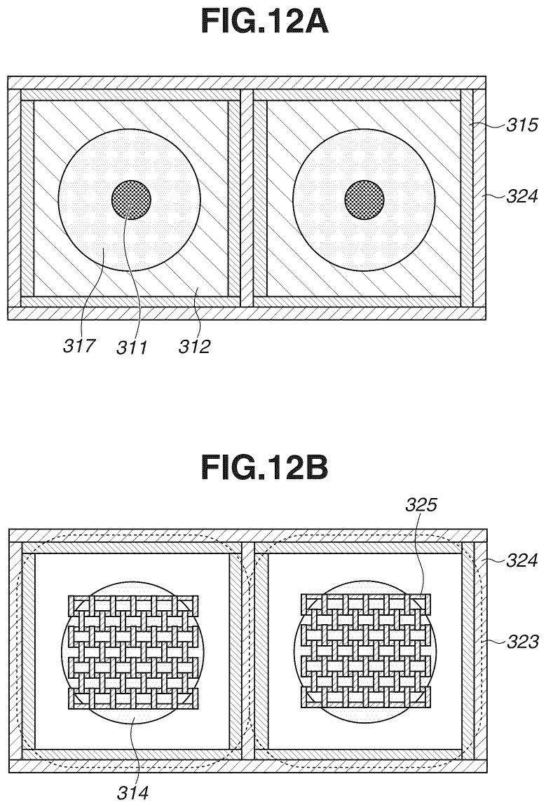

With reference to FIGS. 12A and 12B, a photoelectric conversion apparatus 100 according to a second exemplary embodiment is described.

Descriptions similar to the first exemplary embodiment are omitted, and the differences from the first exemplary embodiment are mainly described. In the present exemplary embodiment, the uneven structure 325 is formed with points where the trenches included in the uneven structure 325 overlap each other in a T-shape in a planar view.

FIGS. 12A and 12B are pixel plan views of the two pixels 101 of the photoelectric conversion apparatus 100 according to the present exemplary embodiment.

In a planar view from the light incident surface, the trenches of the uneven structure 325 are disposed to form a shape in which a T-shaped configuration is repeated so that a plurality of rectangles lines up. It can also be said that the uneven structure 325 is a grid structure in which rows of the trench structure in the grid illustrated in FIGS. 9A and 9B are staggered by half the pitch.

With this configuration, the number of portions over-etched due to the trenches overlapping each other in an etching process for formation of the trenches is smaller than a case where a grid in which the trenches of the uneven structure 325 vertically and horizontally intersect each other is formed. Thus, this configuration reduces the possibility of deterioration in the DCR due to damage such as a grid defect occurring in a semiconductor layer by etching and causing a dark current.

### Variation of Second Exemplary Embodiment

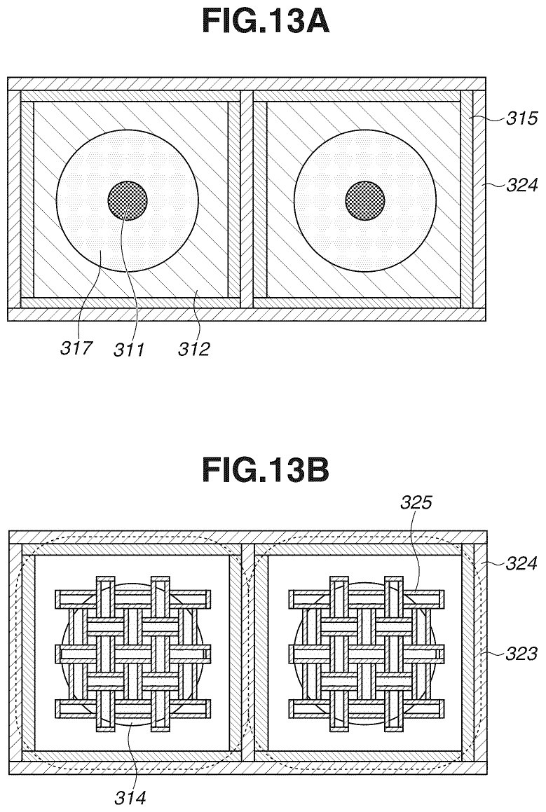

FIGS. 13A and 13B illustrate pixel plan views of two pixels 101 of the photoelectric conversion apparatus 100 according to a variation of the present exemplary embodiment.

In a planar view from the light incident surface, the trenches of the uneven structure 325 are disposed to form a shape in which a T-shaped configuration is repeated so that a plurality of rectangles having different areas lines up.

Also with this configuration, the number of portions over-etched due to the trenches overlapping each other is smaller than a case where a grid in which the trenches of the uneven structure 325 vertically and horizontally overlap each other is formed. Thus, this configuration reduces the possibility of deterioration in the DCR due to damage such as a grid defect occurring in a semiconductor layer by etching and causing a dark current.

### Third Exemplary Embodiment

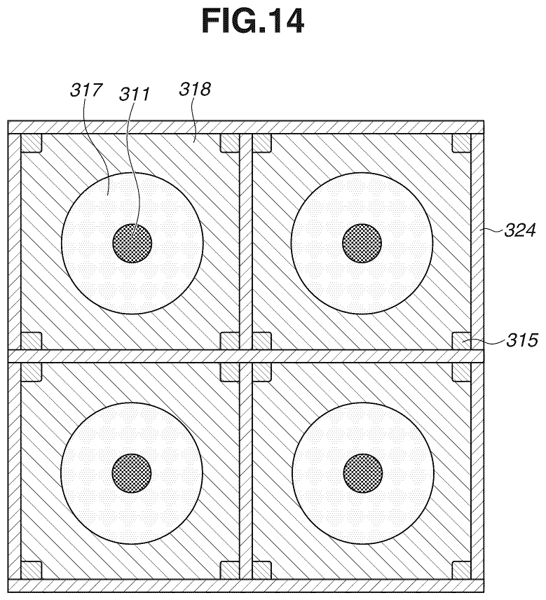

With reference to FIGS. 14 to 17, a photoelectric conversion apparatus 100 according to a third exemplary embodiment is described.

Descriptions similar to the first and second exemplary embodiments are omitted, and the differences from the first exemplary embodiment are mainly described.

FIG. 14 is a pixel plan view of four pixels 101 of the photoelectric conversion apparatus 100 according the present exemplary embodiment in a planar view from the surface facing opposite to the light incident surface. The photoelectric conversion apparatus 100 according the third exemplary embodiment is different from the photoelectric conversion apparatus 100 according to each of the first and second exemplary embodiments in that an eighth semiconductor region 318 of the N-type is disposed around the seventh semiconductor region 317. The N-type impurity concentration of the eighth semiconductor region 318 formed in the surface facing opposite to the light incident surface is lower than the N-type impurity concentration of the first semiconductor region 311.

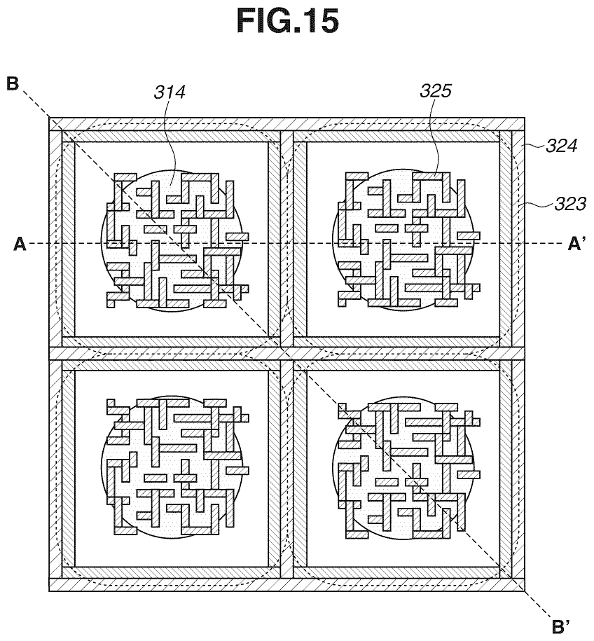

FIG. 15 is a pixel plan view of the four pixels 101 of the photoelectric conversion apparatus 100 according to the present exemplary embodiment in a planar view from the light incident surface.

In the planar view from the light incident surface, the uneven structure 325 has a non-cyclic structure with randomly disposed trenches. Also in this case, the effective pitch of the uneven structure 325 is configured to be shorter than the wavelength of the avalanche light emission light.

The distribution of the uneven structure 325 is randomized, whereby the angle distribution of diffracted light when incident light is diffracted by the uneven structure 325 is uniformized, which leads to increase in the effect of improving sensitivity. The placement of the uneven structure 325 is not limited to this, and for example, a plurality of independent island-shaped structures may be formed in a surface.

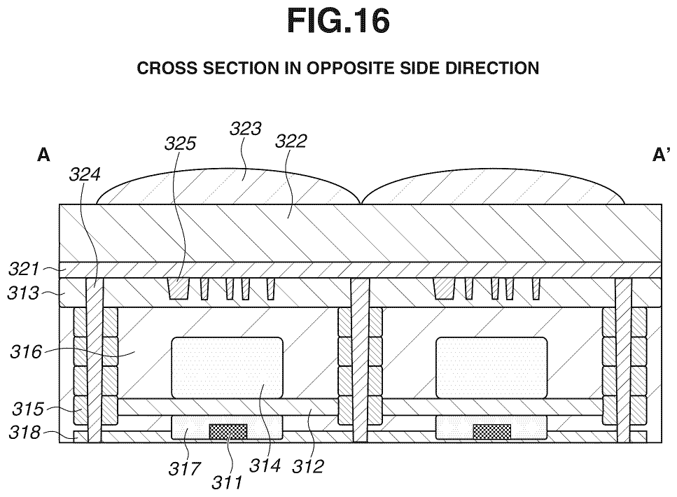

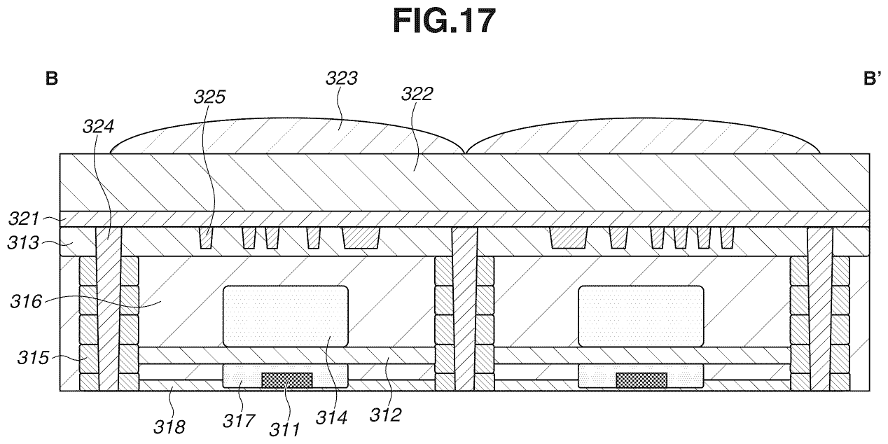

FIG. 16 is a cross-sectional view of the pixels 101 of the photoelectric conversion apparatus 100 according to the present exemplary embodiment along a direction A-A′ in FIG. 15. FIG. 17 is a cross-sectional view of the pixels 101 of the photoelectric conversion apparatus 100 according to the present exemplary embodiment along a direction B-B′ in FIG. 15.

Each of the pixels 101 according to the present exemplary embodiment does not include the fifth semiconductor region 315 extended to the surface facing the light incident surface in the cross section in the direction A-A′ (opposite side direction of the pixel 101).

The fifth semiconductor region 315 and the eighth semiconductor region 318 are separated from each other in this structure. On the other hand, the fifth semiconductor region 315 is extended from the portion close to the light incident surface to the surface facing the light incident surface in the cross section in the direction B-B′ (diagonal direction of the pixel 101).

The fifth semiconductor region 315 is not disposed and the eighth semiconductor region 318 is disposed in corner portions of the pixel 101, whereby an electric field in the planar direction is relaxed. In a case where dark charges are generated in the corner portions of the pixel 101, the dark charges are collected in the first semiconductor region 311 by an electric field in a horizontal direction and are likely to be ejected without passing through an intense electric field region that induces avalanche multiplication.

This reduces the deterioration in the DCR. The fifth semiconductor region 315 is not disposed in the corner portions of the pixel 101, whereby electric field concentration in a horizontal direction between the fifth semiconductor region 315 and the first semiconductor region 311 is prevented. This facilitates the miniaturization of pixels.

### Fourth Exemplary Embodiment

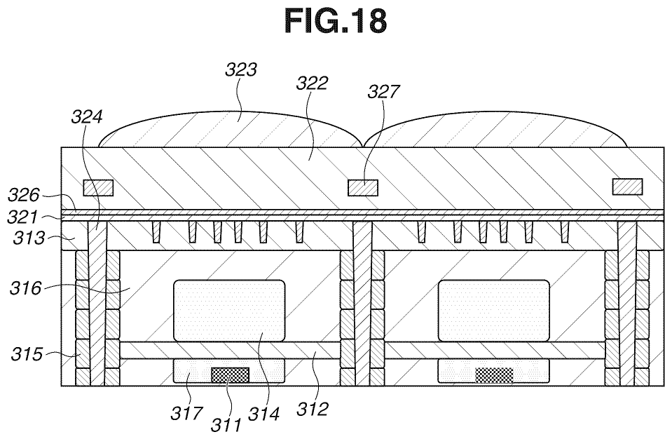

With reference to FIGS. 18 to 20, a photoelectric conversion apparatus 100 according to a fourth exemplary embodiment is described.

Descriptions similar to the first to third exemplary embodiments are omitted, and the differences from the first exemplary embodiment are mainly described.

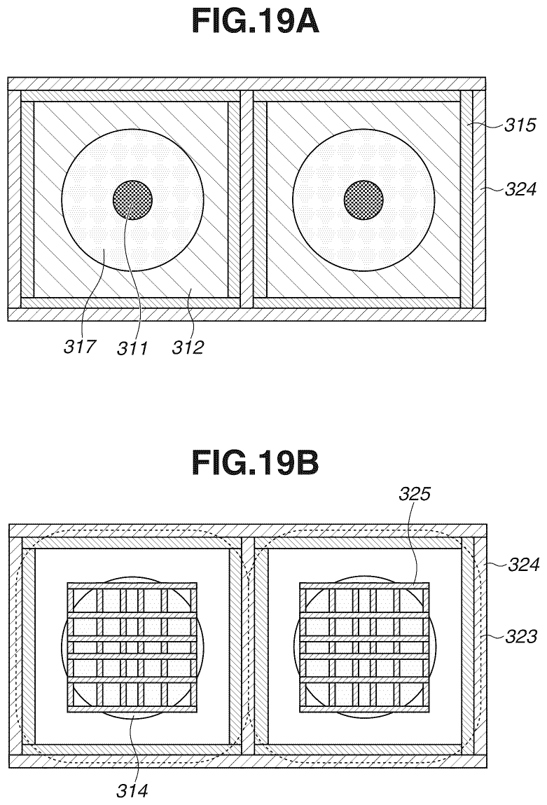

FIG. 18 is a cross-sectional view of two pixels 101 of the photoelectric conversion apparatus 100 according to the present exemplary embodiment. FIGS. 19A and 19B are plan views of the two pixels 101 of the photoelectric conversion apparatus 100 according to the fourth exemplary embodiment. FIG. 19A is a plan view in a planar view from the surface facing opposite to the light incident surface. FIG. 19B is a plan view in a planar view from the light incident surface.

As illustrated in FIGS. 18, 19B. and 19A, in the photoelectric conversion apparatus 100 according to the present exemplary embodiment, an antireflection film 326 is disposed between the first semiconductor layer and the interlayer film (planarization layer) 322. The present exemplary embodiment is different from the first to third exemplary embodiments also in that a light-blocking portion 327 is disposed between the pixels 101, and the uneven structure 325 is formed so that a density distribution occurs in each pixel 101.

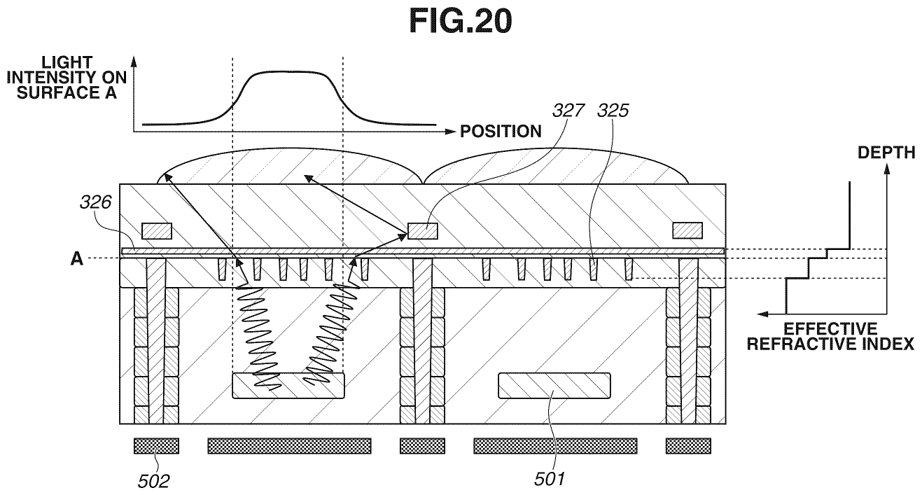

With reference to FIG. 20, which is a diagram illustrating a comparison case of the two pixels 101 of the photoelectric conversion apparatus 100 according to the fourth exemplary embodiment, the effects of the fourth exemplary embodiment are described.

FIG. 20 illustrates the photoelectric conversion apparatus 100 in a simplified manner. The photoelectric conversion apparatus 100 is a photoelectric conversion apparatus including the avalanche multiplication region 501, the wiring layer 502, the uneven structure 325, the antireflection film 326, and the light-blocking portion 327.

The refractive index of the antireflection film 326 is lower than the effective refractive index of the uneven structure 325. The effective refractive index is the substantial refractive index of the while of the uneven structure 325 which is a combination of the substrate on which the trenches are formed and members filling the trenches. For example, in a case where the first semiconductor layer are Si having a refractive index of 4, and the interlayer film 322 is SiO having a refractive index of 1.5, the effective refractive index of the uneven structure 325 is 2.8 to 3.8. For example, the antireflection film 326 is Ta₂O₅, which has a refractive index of about 2. With the antireflection film 326 disposed between the first semiconductor layer and the interlayer film 322, a change in the refractive index from the first semiconductor layer to the interlayer film 322 becomes gradual. Consequently, the reflection of avalanche light emission light from the back surface of the first semiconductor layer is prevented and crosstalk due to the avalanche light emission light is reduced.

Moreover, with the light-blocking portion 327 disposed between the pixels 101, in a case where avalanche light emission light generated in each pixel 101 comes out of the pixel 101, crosstalk caused by the avalanche light emission light entering an adjacent pixel 101 is reduced.

As illustrated in FIG. 19A, the uneven structure 325 according to the present exemplary embodiment is formed so that a density distribution occurs in each pixel 101. Specifically, in each pixel 101, the trench density is low in a peripheral portion of the pixel 101 where the intensity distribution of the avalanche light emission light is low. Consequently, the area occupancy of the trenches in the entirety of the pixel 101 is decreased. Because a portion where the trenches are formed can be a generation source of a dark current due to damage on the first semiconductor layer by etching, a decrease in the area occupancy of the trenches results in a reduction in the DCR in addition to a reduction in crosstalk.

### Fifth Exemplary Embodiment

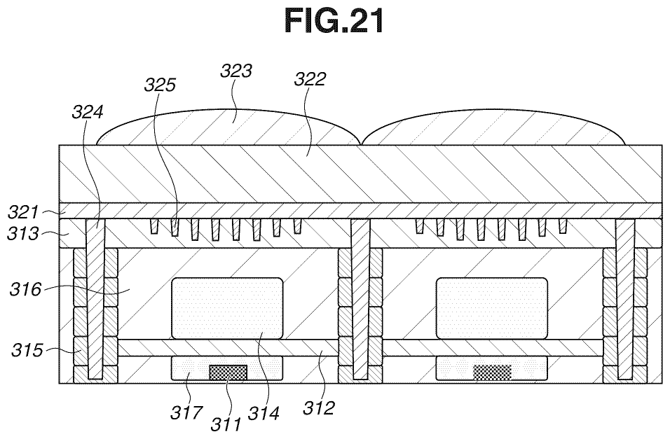

With reference to FIG. 21, a photoelectric conversion apparatus 100 according to a fifth exemplary embodiment is described.

Descriptions similar to the first to fourth exemplary embodiments are omitted, and the differences from the first exemplary embodiment are mainly described.

FIG. 21 is a cross-sectional view of pixels 101 of the photoelectric conversion apparatus 100 according to the present exemplary embodiment.

In the photoelectric conversion apparatus 100 according to the present exemplary embodiment, the depths of the trenches of the uneven structure 325 are not uniform. In each pixel 101 illustrated in FIG. 21, trenches included in a first uneven structure disposed in a portion close to a center portion of the pixel 101 where the intensity of the avalanche light emission light is high are formed at depths of 0.1 to 0.6 μm, for example. On the other hand, trenches included in a second uneven structure disposed in a portion close to an outer edge portion of the pixel 101 where the intensity of the avalanche light emission light is low are formed to be relatively shallow.

As described above, with the uneven structure 325 including a plurality of trenches having different depths, the reflection of light emission light near the center of the pixel 101 where avalanche light emission light is strongly collected is intensively prevented, which reduces crosstalk. Further, the total volume of the uneven structure 325 is reduced, whereby generation of a dark current is prevented, and deterioration in the DCR is reduced.

### Sixth Exemplary Embodiment

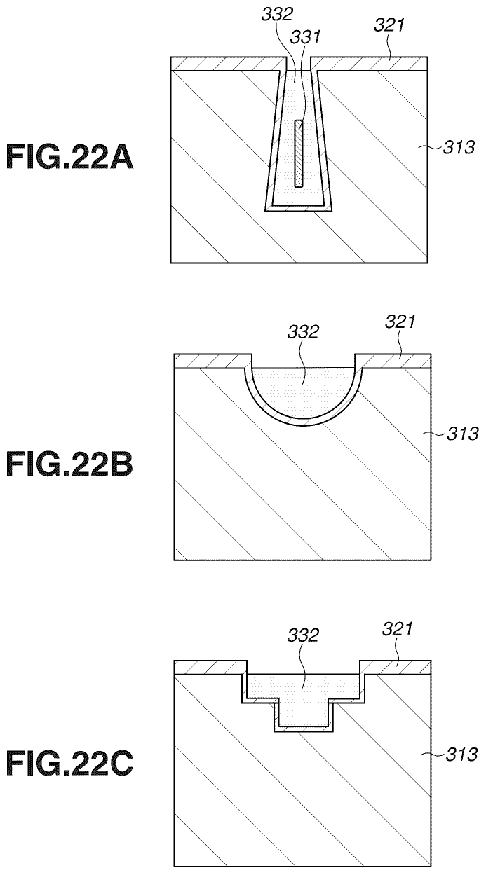

With reference to FIGS. 22A to 22C, a photoelectric conversion apparatus 100 according to a sixth exemplary embodiment is described.

Descriptions similar to the first to fourth exemplary embodiments are omitted, and the differences from the first exemplary embodiment are mainly described.

A cross section of each of the trenches of the uneven structure 325 is not limited to the shape illustrated in FIG. 8, and for example, may be an inverted tapered shape in which the portion close to the light incident surface is narrow and the portion close to the surface facing the light incident surface is wide as illustrated in FIG. 22A. With the trench of the uneven structure 325 having such a shape, the diffraction effect is increased and sensitivity is improved.

Each of the trenches of the uneven structure 325 may be hemispherical as illustrated in FIG. 22B. A steep change in the refractive index is reduced, and the reflection prevention effect is obtained, whereby sensitivity is improved. Although FIG. 22B illustrates a hemisphere having a cross section in a semicircle shape with a central angle of 180°, a similar effect is obtained as long as the trench has a shape with an arc-shaped cross section.

Also with a stair-like trench as illustrated in FIG. 22C, a steep change in the refractive index is similarly reduced, and sensitivity is improved by the reflection prevention effect. Although FIG. 22C illustrates a stair-like trench having two flat surfaces parallel to the light incident surface, the number of parallel surfaces (the number of steps of the stairs) is not limited to this.

### Seventh Exemplary Embodiment

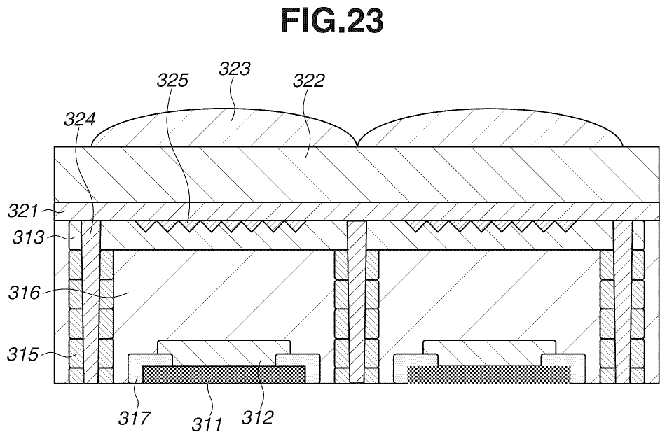

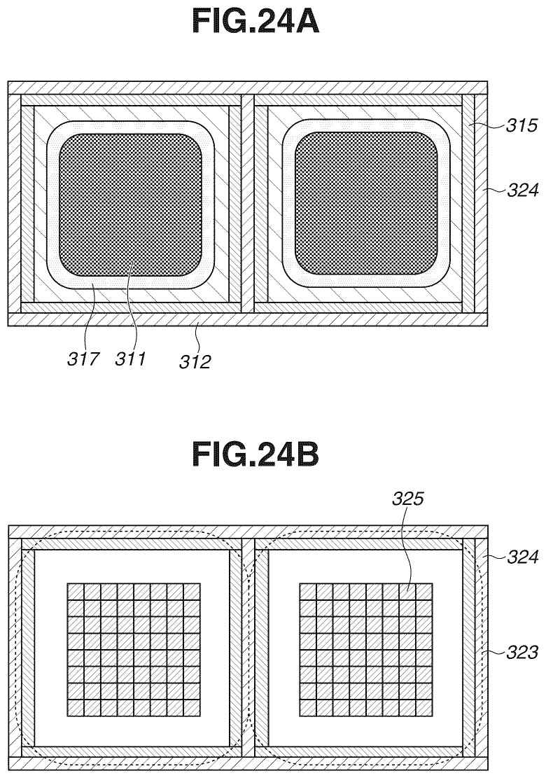

With reference to FIGS. 23, 24A, and 24B, a photoelectric conversion apparatus 100 according to a seventh exemplary embodiment is described.

Descriptions similar to the first to sixth exemplary embodiments are omitted, and the differences from the first exemplary embodiment are mainly described.

FIG. 23 is a cross-sectional view of photoelectric conversion elements 102 of the photoelectric conversion apparatus 100 according to the seventh exemplary embodiment in a direction perpendicular to the surface direction of the first semiconductor layer. In the photoelectric conversion apparatus 100 according to the present exemplary embodiment, the proportion of the first semiconductor region 311 of the N-type to a light-receiving surface of the pixel 101 is greater than the proportion in the photoelectric conversion apparatus 100 according to the first exemplary embodiment, and the seventh semiconductor region 317 is disposed between the first semiconductor region 311 and the second semiconductor region 312.

The uneven structure 325 has a square pyramid shape with a triangle cross section having the bottom surface at the light incident surface.

FIGS. 24A and 24B are pixel plan views of two pixels 101 of the photoelectric conversion apparatus 100 according to the seventh exemplary embodiment. FIG. 24A is a plan view in a planar view from the surface facing opposite to the light incident surface. FIG. 24B is a plan view in a planar view from the light incident surface.

In the planar view from the light incident surface, the third semiconductor region 313 is disposed between the first semiconductor region 311 and the second semiconductor region 312. Incident light is avalanche-multiplied between the first semiconductor region 311 and the second semiconductor region 312. Thus, in a case where an opening portion of the pixel 101 is designed to expose the first semiconductor region 311 and the second semiconductor region 312, the aperture ratio of the photoelectric conversion apparatus 100 according to the present exemplary embodiment is smaller than the aperture ratio of the photoelectric conversion apparatus 100 according to each of the first to fifth exemplary embodiments. With the small aperture ratio, the volume of a photoelectric conversion region where a signal can be detected is reduced, which reduces crosstalk.

### Eighth Exemplary Embodiment

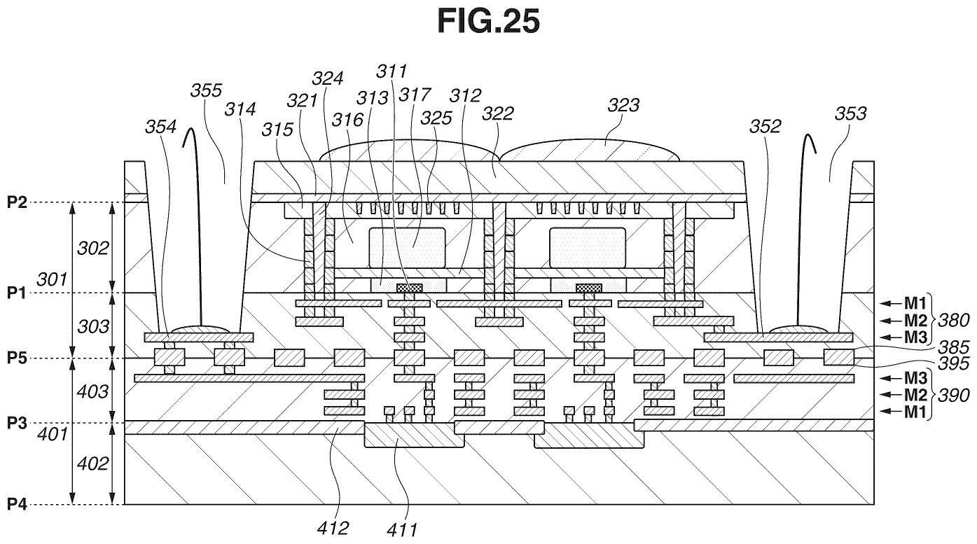

With reference to FIG. 25, a photoelectric conversion apparatus 100 according to an eighth exemplary embodiment is described.

Descriptions similar to the first to seventh exemplary embodiments are omitted, and the differences from the first exemplary embodiment are mainly described.

FIG. 25 is a cross-sectional view of the photoelectric conversion apparatus 100. Light is incident from the upper side in FIG. 25. A first substrate 301 and a second substrate 401 are stacked from the light incident surface.

The first substrate 301 includes a first substrate semiconductor layer (first semiconductor layer) 302 and a first substrate wiring structure (first wiring structure) 303. The second substrate 401 includes a second substrate semiconductor layer (second semiconductor layer) 402 and a second substrate wiring structure (second wiring structure) 403. The first semiconductor layer 302 includes a first surface P1 on one side and a second surface P2 on the opposite side of the first surface P1. For example, the first surface P1 is a front surface, and the second surface P2 is a back surface. The second semiconductor layer 402 includes a third surface P3 on one side and a fourth surface P4 on the opposite side of the third surface P3. For example, the third surface P3 is a front surface, and the fourth surface P4 is a back surface. The first substrate 301 and the second substrate 401 are joined together so that the first wiring structure 303 and the second wiring structure 403 are faced and in contact with each other. The joint surface is a fifth surface P5. The fifth surface P5 can be an upper surface of the first wiring structure 303 and can be an upper surface of the second wiring structure 403.

In the first semiconductor layer 302, a first semiconductor region 311 of a first conductivity type, a second semiconductor region 312 of a second conductivity type, a third semiconductor region 313 of the first conductivity type, and a fourth semiconductor region 314 of the second conductivity type are disposed. In the first semiconductor layer 302, a fifth semiconductor region 315 of the second conductivity type, a sixth semiconductor region 316 of the first conductivity type, and a seventh semiconductor region 317 of the first conductivity type are further disposed.

The first semiconductor region 311 and the second semiconductor region 312 form a P-N junction and configure an APD.

The third semiconductor region 313 is formed in a portion closer to the light incident surface than the second semiconductor region 312. The impurity concentration of the third semiconductor region 313 is lower than the impurity concentration of the second semiconductor region 312. The term “impurity concentration” means a net impurity concentration obtained by subtracting compensation by impurities of the opposite conductivity type. That is, an “impurity concentration” refers to a net concentration. For example, a region where a P-type added impurity concentration is higher than an N-type added impurity concentration is a P-type semiconductor region. Conversely, a region where an N-type added impurity concentration is higher than a P-type added impurity concentration is an N-type semiconductor region.

The pixels 101 are separated from each other by the fourth semiconductor region 314. The fifth semiconductor region 315 is disposed in a portion closer to the light incident surface than the fourth semiconductor region 314. The fifth semiconductor region 315 is disposed in common to the pixels 101.

A voltage VPDL (first voltage) is supplied to the fourth semiconductor region 314. A voltage VDD (second voltage) is supplied to the first semiconductor region 311. Due to the voltage VPDL supplied to the fourth semiconductor region 314 and the voltage VDD supplied to the first semiconductor region 311, reverse bias voltages are supplied to the second semiconductor region 312 and the first semiconductor region 311. Consequently, the reverse bias voltages that cause the APD to perform an avalanche multiplication operation are supplied.

A pinning layer 321 is disposed on the light incident surface side of the fifth semiconductor region 315. The pinning layer 321 is a layer disposed to reduce a dark current. The pinning layer 321 is formed using hafnium oxide (HfO₂), for example. The pinning layer 321 may also be formed using zirconium dioxide (ZrO₂) or tantalum oxide (Ta₂O₅).

The planarization layer 322 and the microlens 323 are disposed on the pinning layer 321. The planarization layer 322 can include any component, such as an insulator film, a light-blocking film, or a color filter. Between the microlens 323 and the pinning layer 321, a light-blocking film having a grid shape to optically separate the pixels 101 may be disposed. The light shielding film can be any material as long as the material shields light. For example, tungsten (W), aluminum (Al), or copper (Cu) can be used.

In the second semiconductor layer 402, an active region 411 composed of a semiconductor region and a separation region 412 are disposed. The separation region 412 is a field region including an insulator.

The first wiring structure 303 includes a plurality of insulator layers and a plurality of wiring layers 380. The plurality of wiring layers 380 includes a first wiring layer (M1), a second wiring layer (M2), and a third wiring layer (M3) in this order from the first semiconductor layer 302. In the uppermost layer of the first wiring structure 303, a first joint portion 385 is disposed in an exposed manner. In the first wiring structure 303, a first pad opening 353 and a second pad opening 355 are formed. In bottom portions of the first pad opening 353 and the second pad opening 355, a first pad electrode 352 and a second pad electrode 354, respectively, are disposed. To each of the first pad electrode 352 and the second pad electrode 354, a voltage is supplied from the outside of the photoelectric conversion apparatus 100. The outside of the photoelectric conversion apparatus 100 and each of the pad electrodes 352 and 354 are electrically connected together by wire bonding illustrated in FIG. 25, a joint using solder, or a through-silicon via (TSV). The first pad electrode 352 is an electrode for supplying a voltage to a circuit of the first substrate 301. For example, the first pad electrode 352 supplies the voltage VPDL (first voltage) to the fourth semiconductor region 314 via a via wire (not illustrated) or a contact wire (not illustrated).

The second wiring structure 403 includes a plurality of insulator layers and a plurality of wiring layers 390. The plurality of wiring layers 390 includes a first wiring layer (M1), a second wiring layer (M2), and a third wiring layer (M3) in this order from the second semiconductor layer 402. In the uppermost layer of the second wiring structure 403, a second joint portion 395 is disposed in an exposed manner. The first joint portion 385 of the first substrate 301 is in contact with and electrically connected to the second joint portion 395 of the second substrate 401. The joint between the first joint portion 385 thus exposed through a joint surface of the first substrate 301 and the second joint portion 395 thus exposed through a joint surface of the second substrate 401 is occasionally referred to as a “metal bonding (MB) structure” or a “metal joint portion”. This joint is often performed by copper (Cu) and copper (Cu) and therefore is occasionally referred to as a “Cu—Cu joint (Cu—Cu bonding)”. The joint between the first joint portion 385 and the second joint portion 395 and the joint between the insulator layers of the first wiring structure 303 and the insulator layers of the second wiring structure 403 are occasionally referred to as “hybrid bonding”.

The second pad electrode 354 disposed in the first wiring structure 303 is electrically connected to any of a plurality of wires disposed in the plurality of wiring layers 390 via the first joint portion 385 and the second joint portion 395. For example, the second pad electrode 354 supplies a voltage VSS (third voltage) to a circuit disposed in a pixel circuit. The second pad electrode 354 also supplies the voltage VDD (second voltage) to a circuit disposed in the pixel circuit. Further, the second pad electrode 354 supplies a voltage to any of the wires in the plurality of wiring layers 390 via the first joint portion 385 and the second joint portion 395 and supplies a voltage to any of wires in the plurality of wiring layers 380 via the second joint portion 395 and the first joint portion 385. For example, in such a path, the voltage VDD (second voltage) electrically connected to a quench element is supplied from the second pad electrode 354.

Specifically, the second pad electrode 354 supplies the voltage VDD (second voltage) to the first joint portion 385, the second joint portion 395, and any of the wires in the plurality of wiring layers 390. Then, the voltage VDD (second voltage) is supplied from the wire in the plurality of wiring layers 390 to the first semiconductor region 311 via the quench element disposed in the second substrate 401, the wires in the plurality of wiring layers 390, the second joint portion 395, and the first joint portion 385. While FIG. 25 illustrates only a single pad electrode as the second pad electrode 354, a plurality of second pad electrodes 354 may be disposed to supply voltages having different values.

In FIG. 25, the first pad electrode 352 and the second pad electrode 354 are disposed between the second surface P2 and the fifth surface P5, more specifically, between the first surface P1 and the fifth surface P5. The first pad electrode 352 and the second pad electrode 354 can be disposed between the second surface P2 and the fourth surface P4.

### Ninth Exemplary Embodiment

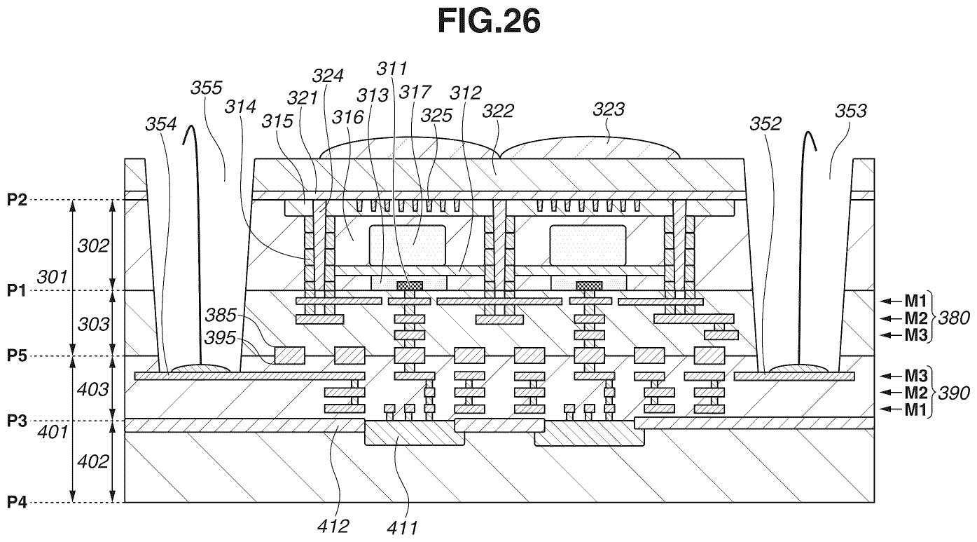

With reference to FIG. 26, a photoelectric conversion apparatus 100 according to a ninth exemplary embodiment is described.

Descriptions similar to the first to eighth exemplary embodiments are omitted, and the differences from the first exemplary embodiment are mainly described.

FIG. 26 illustrates a variation of the photoelectric conversion apparatus 100. FIG. 26 corresponds to the cross-sectional view illustrated in FIG. 6. In the present exemplary embodiment, the positions of the first pad electrode 352 and the second pad electrode 354 are changed from the configuration of the first exemplary embodiment.

In FIG. 25, a wiring layer of the first wiring structure 303, e.g., the third wiring layer, includes the first pad electrode 352 and the second pad electrode 354. In FIG. 26, however, a wiring layer of the second wiring structure 403, e.g., the third wiring layer, includes the first pad electrode 352 and the second pad electrode 354. The depth of the first pad opening 353 and the second pad opening 355 illustrated in FIG. 26 is greater than the depth of the first pad opening 353 and the second pad opening 355 illustrated in FIG. 25. For example, the term “depth” means the distance from the back surface of the semiconductor layer 302. The first pad electrode 352 and the second pad electrode 354 can be disposed between the fifth surface P5 and the fourth surface P4, and for example, are disposed between the fifth surface P5 and the third surface P3. For example, the back surface of the semiconductor layer 302 is an interface with the pinning layer 321. The first pad opening 353 and the second pad opening 355 penetrate the joint surface and extend from the semiconductor layer 302. The photoelectric conversion apparatus 100 according to the present invention can also employ this configuration. While a configuration in which a wiring layer includes the first pad electrode 352 and the second pad electrode 354 has been described, a pad electrode may be formed separately from a wiring layer.

### Tenth Exemplary Embodiment

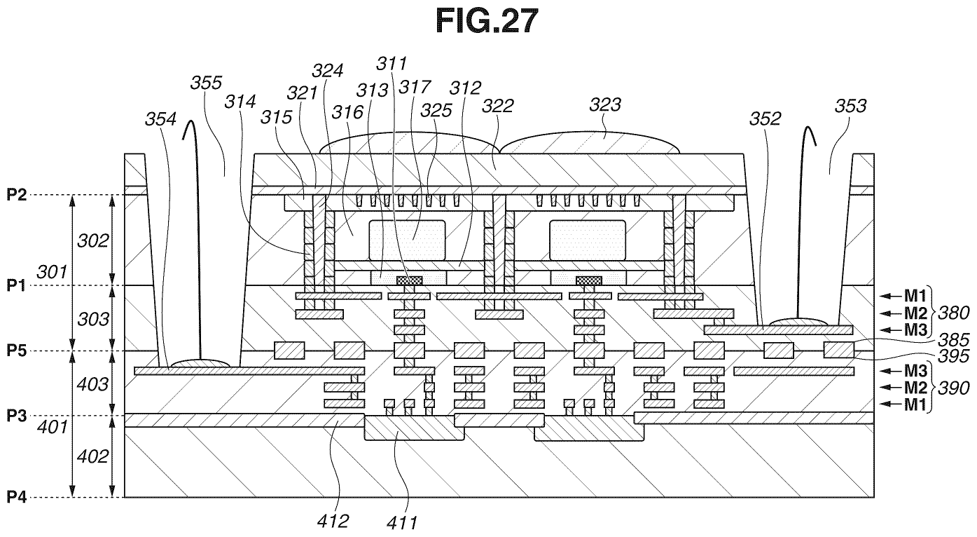

With reference to FIG. 27, a photoelectric conversion apparatus 100 according to a tenth exemplary embodiment is described.

Descriptions similar to the first to ninth exemplary embodiments are omitted, and the differences from the first exemplary embodiment are mainly described.

FIG. 27 illustrates a variation of the photoelectric conversion apparatus 100. FIG. 27 corresponds to the cross-sectional view illustrated in FIG. 6. In the present exemplary embodiment, the position of the second pad electrode 354 is changed from the configuration of the eighth exemplary embodiment.

In FIG. 25, a wiring layer of the first wiring structure 303, e.g., the third wiring layer M3, includes the second pad electrode 354. In FIG. 27, however, a wiring layer of the second wiring structure 403, e.g., the third wiring layer M3, includes the second pad electrode 354. That is, the second pad electrode 354 can be disposed between the fifth surface P5 and the fourth surface P4, and for example, is disposed between the fifth surface P5 and the third surface P3. The first pad electrode 352 can be disposed between the second surface P2 and the fifth surface P5, and for example, is disposed between the first surface P1 and the fifth surface P5. Alternatively, a wiring layer of the second wiring structure 403 may include the first pad electrode 352, and a wiring layer of the first wiring structure 303 may include the second pad electrode 354. The photoelectric conversion apparatus 100 according to the present invention can also employ this configuration.

While a configuration in which wiring layers include the first pad electrode 352 and the second pad electrode 354 has been described, a pad electrode may be formed separately from a wiring layer.

### Eleventh Exemplary Embodiment

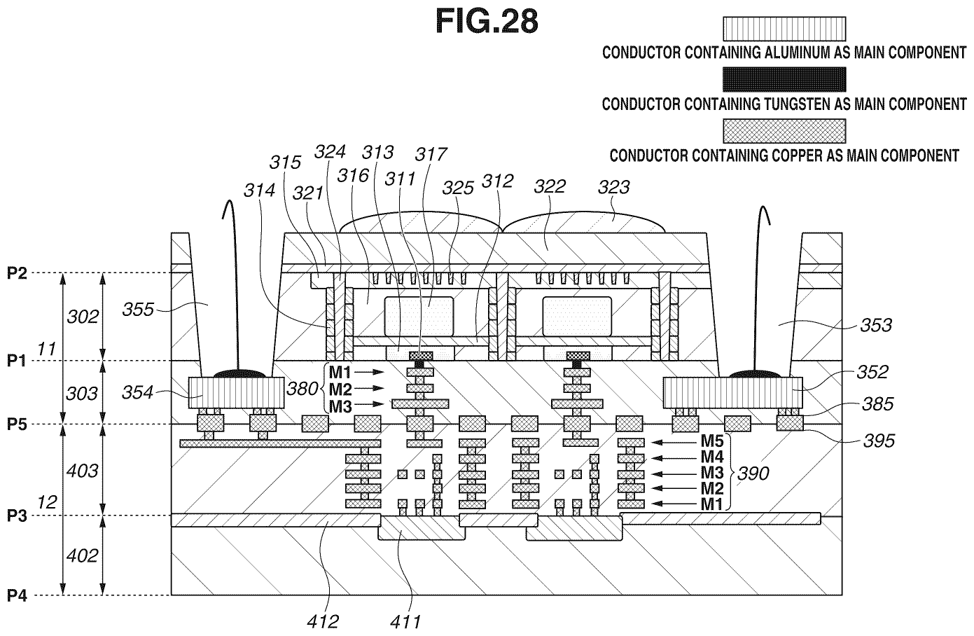

With reference to FIG. 28, a photoelectric conversion apparatus 100 according to an eleventh exemplary embodiment is described.

Descriptions similar to the first to tenth exemplary embodiments are omitted, and the differences from the eighth exemplary embodiment are mainly described.

FIG. 28 illustrates a variation of the photoelectric conversion apparatus 100. FIG. 27 corresponds to the cross-sectional view illustrated in FIG. 6. In the present exemplary embodiment, the structures of the first pad electrode 352 and the second pad electrode 354 are changed from the configuration of the eighth exemplary embodiment.

The first wiring structure 303 includes a first wiring layer M1, a second wiring layer M2, a third wiring layer M3, and a joint portion 385. The second wiring structure 403 includes a first wiring layer M1, a second wiring layer M2, a third wiring layer M3, a fourth wiring layer M4, a fifth wiring layer M5, and a joint portion 395. Each wiring layer is a so-called copper wire.

In each of the wiring structures 303 and 403, the first wiring layer M1 has a conductor pattern containing copper as a main component. The conductor pattern of the first wiring layer M1 has a single-damascene structure. Contacts are disposed to electrically connect the first wiring layer M1 and the semiconductor layer 302. The contacts have a conductor pattern containing tungsten as a main component. Each of the second wiring layer M2 and the third wiring layer M3 has a conductor pattern containing copper as a main component. Each of the conductor patterns of the second wiring layer M2 and the third wiring layer M3 has a dual-damascene structure and includes a portion that functions as a wire and a portion that functions as a via. The fourth wiring layer M4 and the fifth wiring layer M5 are also similar to the second wiring layer M2 and the third wiring layer M3.

Each of the first pad electrode 352 and the second pad electrode 354 has a conductor pattern containing aluminum as a main component. The first pad electrode 352 and the second pad electrode 354 are disposed in and extended over the second wiring layer M2 and the third wiring layer M3 of the wiring structure 303. For example, each of the first pad electrode 352 and the second pad electrode 354 includes a portion that functions as a via connecting the first wiring layer M1 and the second wiring layer M2 and a portion that functions as a wire of the third wiring layer M3. For example, the first pad electrode 352 and the second pad electrode 354 are disposed between the first surface P1 and the fifth surface P5. The first pad electrode 352 and the second pad electrode 354 can be disposed between the second surface P2 and the fourth surface P4 and can also be disposed between the second surface P2 and the fifth surface P5.

Each of the first pad electrode 352 and the second pad electrode 354 includes a first surface on one side and a second surface on the opposite side of the first surface. A part of the first surface is exposed through an opening of the semiconductor layer 302.

The exposed portion of each of the first pad electrode 352 and the second pad electrode 354 can function as a connection portion with an external terminal, i.e., a so-called pad portion. The first pad electrode 352 and the second pad electrode 354 are connected to a plurality of conductors containing copper as a main component on the second surfaces of the pad electrodes 352 and 354.

As another form of the present exemplary embodiment, a portion of each of the first pad electrode 352 and the second pad electrode 354 not exposed on the first surface can also include an electrical connection portion. For example, each of the first pad electrode 352 and the second pad electrode 354 may include a via composed of a conductor containing aluminum as a main component, and may be electrically connected via the via to a conductor that contains copper as a main component and is disposed on the first surface. Alternatively, each of the first pad electrode 352 and the second pad electrode 354 may be connected to the first wiring layer M1 of the first wiring structure 303 on the first surface using a conductor containing tungsten as a main component.

For example, the first pad electrode 352 and the second pad electrode 354 can be formed by the following procedure. In formation of the first pad electrode 352 and the second pad electrode 354, an insulator covering the third wiring layer M3 is formed, a part of the insulator is removed, a film containing aluminum as a main component to be the first pad electrode 352 and the second pad electrode 354 is formed, and patterning is performed to form the first pad electrode 352 and the second pad electrode 354. After a copper wire is formed, the first pad electrode 352 and the second pad electrode 354 are formed, whereby the first pad electrode 352 and the second pad electrode 354 having thick film thickness with a flat fine copper wire is formed.

While a case in which the first pad electrode 352 and the second pad electrode 354 according to the present exemplary embodiment are included in the first wiring structure 303, the first pad electrode 352 and the second pad electrode 354 may be included in the second wiring structure 403. The position where a pad electrode is disposed may be in either of the wiring structures 303 and 403, and is not limited. The material and the structure of each of the wiring layers of the wiring structures 303 and 403 are not limited to those exemplified, and for example, a conductor layer may be further disposed between the first wiring layer M1 and the semiconductor layer 302.

Alternatively, the photoelectric conversion apparatus 100 may have a stacked contact structure in which contacts are stacked in two layers.

### Twelfth Exemplary Embodiment

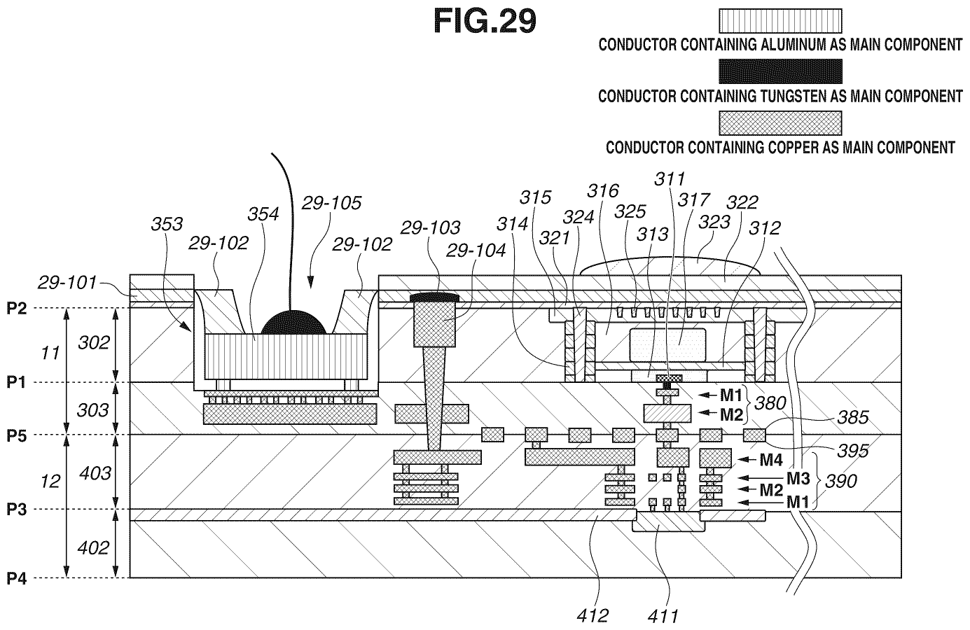

With reference to FIG. 29, a photoelectric conversion apparatus 100 according to a twelfth exemplary embodiment is described.

Descriptions similar to the first to eleventh exemplary embodiments are omitted, and the differences from the eighth exemplary embodiment are mainly described.

FIG. 29 illustrates a variation of the photoelectric conversion apparatus 100. FIG. 29 is a cross-sectional view obtained by enlarging the neighborhood of the pad electrode 354 in the cross-sectional view illustrated in FIG. 25. In the present exemplary embodiment, the structure of the second pad electrode 354 is mainly changed from the configuration of the eighth exemplary embodiment.

The first wiring structure 303 includes a first wiring layer M1, a second wiring layer M2, and a joint portion 385. The second wiring structure 403 includes a first wiring layer M1, a second wiring layer M2, a third wiring layer M3, a fourth wiring layer M4, and a joint portion 395. Each wiring layer is a so-called copper wire.

In each of the wiring structures 303 and 403, the first wiring layer M1 has a conductor pattern containing copper as a main component. The conductor pattern of the first wiring layer M1 has a single-damascene structure. Contacts are disposed to electrically connect the first wiring layer M1 and the semiconductor layer 302. The contacts have a conductor pattern containing tungsten as a main component. Each of the second wiring layer M2 and the third wiring layer M3 has a conductor pattern containing copper as a main component. Each of the conductor patterns of the second wiring layer M2 and the third wiring layer M3 has a dual-damascene structure and includes a portion that functions as a wire and a portion that functions as a via. The fourth wiring layer M4 is also similar to the second wiring layer M2 and the third wiring layer M3.

The second pad electrode 354 has a conductor pattern containing aluminum as a main component. The second pad electrode 354 is disposed not in the wiring structures but in an opening of the semiconductor layer 302. Although a configuration has been illustrated in which the second pad electrode 354 includes an exposed surface between the second surface P2 and the first surface P1, the exposed surface of the second pad electrode 354 may be disposed above the second surface P2.

A method for forming this structure is briefly described. An opening 353 is formed in the semiconductor layer 302 so that a part of the first wiring layer M1 of the first wiring structure 303 is exposed. Then, an insulator 29-101 is formed to cover the second surface P2 of the semiconductor layer 302 and the first pad opening 353. An opening to be a via for the second pad electrode 354 is formed in the insulator 29-101.

After a conductive film to be the second pad electrode 354 is formed, an unnecessary portion of the conductive film is removed to obtain a desired pattern. Further, after an insulator 29-102 is formed, an opening 29-105 through which the second pad electrode 354 is exposed is formed. The above-described configuration can be formed by this method.

Alternatively, a through electrode 29-104 may be disposed from the second surface P2. The through electrode 29-104 may be composed of a conductor containing copper as a main component, and may include a barrier metal between the semiconductor layer 302 and the conductor.

On the through electrode 29-104, a conductor 29-103 is disposed. The conductor 29-103 may be disposed in common with another through electrode, and may have the function of reducing the diffusion of the conductor of the through electrode 29-104.

The first pad electrode 352 (not illustrated) may have a configuration similar to that of the second pad electrode 354. The material and the structure of each of the wiring layers of the wiring structures 303 and 403 are not limited to those exemplified, and for example, a conductor layer may be further included between the first wiring layer M1 and the semiconductor layer 302. Alternatively, the photoelectric conversion apparatus 100 may have a stacked contact structure in which contacts are stacked in two layers.

While the first pad electrode 352 and the second pad electrode 354 are disposed between the second surface P2 and the fourth surface P4, the first pad electrode 352 and the second pad electrode 354 may be disposed on the second surface P2.

Alternatively, the first pad opening 353 and the second pad opening 355 may be disposed in the second substrate 401. In a case where the openings 353 and 355 are disposed in the second substrate 401, a through electrode may be formed in each of the openings 353 and 355. An electrical connection portion between the through electrode and an external apparatus can be disposed on the fourth surface P4.

Alternatively, a pad electrode as an electrical connection portion with an external apparatus may be disposed on both the fourth surface P4 side of the second substrate 401 and the second surface P2 side of the first substrate 301.

### Thirteenth Exemplary Embodiment

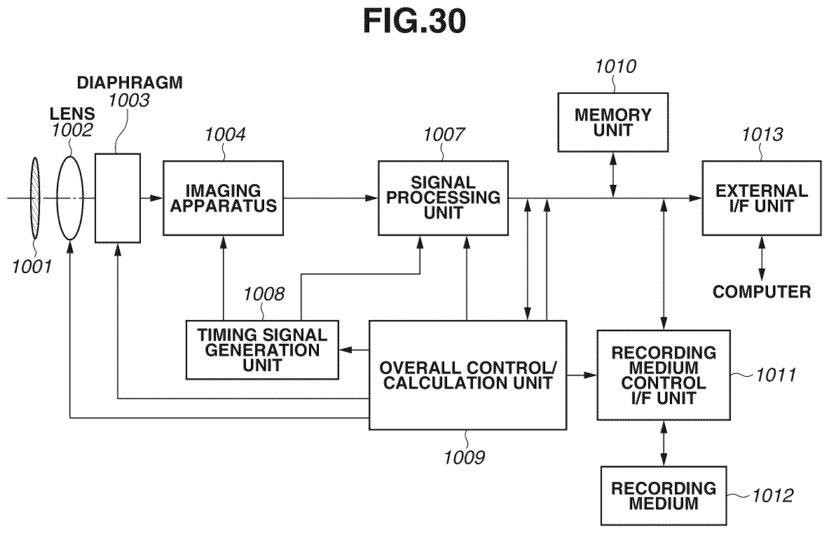

With reference to FIG. 30, a photoelectric conversion system according to a thirteenth exemplary embodiment is described. FIG. 30 is a block diagram illustrating a general configuration of the photoelectric conversion system according to the present exemplary embodiment.

The photoelectric conversion apparatus described in each of the first to twelfth exemplary embodiments is applicable to various photoelectric conversion systems.

Examples of the various photoelectric conversion systems include a digital still camera, a digital camcorder, a monitoring camera, a copying machine, a fax, a mobile phone, an in-vehicle camera, and an observation satellite. The various photoelectric conversion systems also include a camera module including an optical system, such as a lens and an imaging apparatus. FIG. 30 illustrates a block diagram of a digital still camera as one of these examples.

The photoelectric conversion system illustrated in FIG. 30 includes an imaging apparatus 1004, which is an example of the photoelectric conversion apparatus, and a lens 1002 that forms an optical image of a subject on the imaging apparatus 1004. The photoelectric conversion system further includes a diaphragm 1003 for varying an amount of light passing through the lens 1002, and a barrier 1001 for protecting the lens 1002.

The lens 1002 and the diaphragm 1003 serves as an optical system that collects light onto the imaging apparatus 1004. The imaging apparatus 1004 is the photoelectric conversion apparatus according to any of the above-described exemplary embodiments and converts the optical image formed by the lens 1002 into an electric signal.

The photoelectric conversion system further includes a signal processing unit 1007 serving as an image generation unit that processes an output signal output from the imaging apparatus 1004, to generate an image. The signal processing unit 1007 performs an operation of performing various types of correction and compression as necessary and outputting image data. The signal processing unit 1007 may be formed on a semiconductor substrate in which the imaging apparatus 1004 is disposed, or may be formed on a semiconductor substrate different from the imaging apparatus 1004.

The photoelectric conversion system further includes a memory unit 1010 for temporarily storing image data, and an external interface unit (external I/F unit) 1013 for communicating with an external computer. The photoelectric conversion system further includes a recording medium 1012, such as a semiconductor memory, for recording therein or reading therefrom captured data, and a recording medium control interface unit (recording medium control I/F unit) 1011 for recording or reading image data in or from the recording medium 1012. The recording medium 1012 may be built into the photoelectric conversion system or may be attachable to and detachable from the photoelectric conversion system.

Further, the photoelectric conversion system according to the present exemplary embodiment includes an overall control/calculation unit 1009 that performs various calculations and controls the entire operation of the digital still camera, and a timing signal generation unit 1008 that outputs various timing signals to the imaging apparatus 1004 and the signal processing unit 1007. The timing signals may be input from outside, and the photoelectric conversion system may be required to include at least the imaging apparatus 1004 and the signal processing unit 1007 that processes an output signal output from the imaging apparatus 1004.

The imaging apparatus 1004 outputs an imaging signal to the signal processing unit 1007. The signal processing unit 1007 performs predetermined signal processing on the imaging signal output from the imaging apparatus 1004 and outputs image data. The signal processing unit 1007 generates an image using the imaging signal.

As described above, according to the present exemplary embodiment, it is possible to achieve a photoelectric conversion system to which the photoelectric conversion apparatus (the imaging apparatus) according to any of the above-described exemplary embodiments is applied.

### Fourteenth Exemplary Embodiment

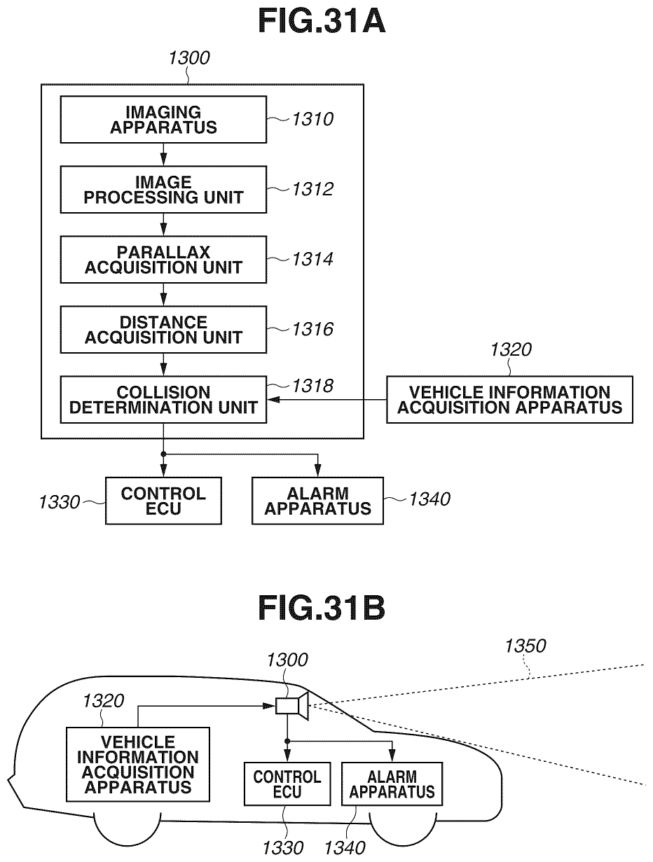

With reference to FIGS. 31A and 31B, a photoelectric conversion system and a movable body according to a fourteenth exemplary embodiment are described. FIGS. 31A and 31B are diagrams illustrating the configurations of the photoelectric conversion system and the movable body according to the present exemplary embodiment.

FIG. 31A illustrates an example of a photoelectric conversion system regarding an in-vehicle camera. A photoelectric conversion system 1300 includes an imaging apparatus 1310. The imaging apparatus 1310 is the photoelectric conversion apparatus according to any of the above-described exemplary embodiments. The photoelectric conversion system 1300 includes an image processing unit 1312 that performs image processing on a plurality of pieces of image data acquired by the imaging apparatus 1310, and a parallax acquisition unit 1314 that calculates a parallax (phase difference between parallax images) from the plurality of pieces of image data acquired by the photoelectric conversion system 1300. The photoelectric conversion system 1300 further includes a distance acquisition unit 1316 that calculates a distance from a target object based on the calculated parallax, and a collision determination unit 1318 that determines whether there is a possibility of a collision, based on the calculated distance. The parallax acquisition unit 1314 and the distance acquisition unit 1316 are examples of a distance information acquisition unit that acquires distance information regarding the distance from a target object. That is, the distance information is information regarding the parallax, the amount of defocus, and the distance from the target object. Any of these pieces of distance information may be used by the collision determination unit 1318 to determine the possibility of a collision. The distance information acquisition unit may be achieved by exclusively designed hardware, or may be achieved by a software module. Alternatively, the distance information acquisition unit may be achieved by a field-programmable gate array (FPGA) or an application-specific integrated circuit (ASIC), or may be achieved by the combination of these.

The photoelectric conversion system 1300 is connected to a vehicle information acquisition apparatus 1320 and can acquire vehicle information, such as a vehicle speed, a yaw rate, and a steering angle. The photoelectric conversion system 1300 is also connected to a control electronic control unit (ECU) 1330 that is a control unit that produces a braking force in the vehicle based on a determination result of the collision determination unit 1318. The photoelectric conversion system 1300 is also connected to an alarm apparatus 1340 that gives an alarm to a driver based on a determination result of the collision determination unit 1318. For example, if there is a high possibility of a collision as the determination result of the collision determination unit 1318, the control ECU 1330 performs braking, releasing an accelerator, or suppressing engine output, to control the vehicle to avoid a collision and reduce damage. The alarm apparatus 1340 warns a user by setting off an alarm such as a sound, displaying alarm information on a screen of an automotive navigation system, or imparting a vibration to a seat belt or the steering.

In the present exemplary embodiment, the photoelectric conversion system 1300 captures the periphery, such as the front direction or the rear direction, of the vehicle. FIG. 31B illustrates the photoelectric conversion system 1300 in a case where the photoelectric conversion system 1300 captures the front direction of the vehicle (an imaging range 1350). The vehicle information acquisition apparatus 1320 sends an instruction to the photoelectric conversion system 1300 or the imaging apparatus 1310. With this configuration, the accuracy of distance measurement can be further improved.

In the above description, an example has been described where a vehicle is controlled to avoid colliding with another vehicle. Alternatively, the present exemplary embodiment is also applicable to control for autonomous driving to follow another vehicle or control for autonomous driving to avoid a deviation from a lane. Furthermore, the photoelectric conversion system can be applied not only to a vehicle such as an automobile but also to a movable body (a moving apparatus), such as a vessel, an aircraft, or an industrial robot. Moreover, in addition to a movable body, the photoelectric conversion system can be applied to a device extensively using object recognition, such as an intelligent transportation system (ITS).

### Fifteenth Exemplary Embodiment

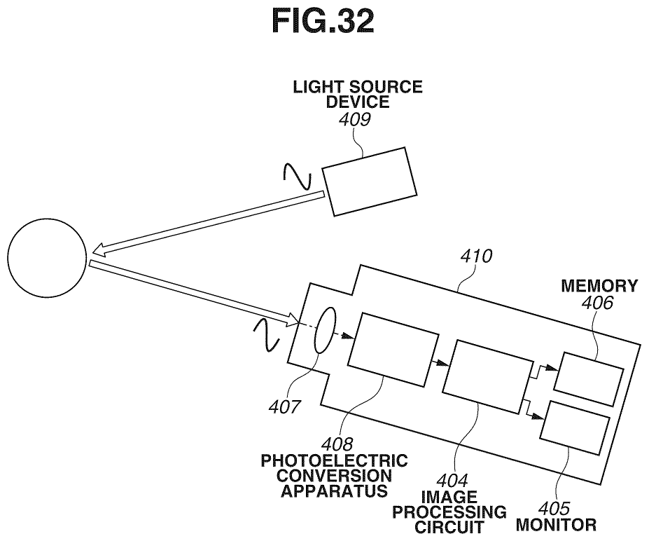

With reference to FIG. 32, a photoelectric conversion system according to a fifteenth exemplary embodiment is described. FIG. 32 is a block diagram illustrating an example of the configuration of a distance image sensor that includes the photoelectric conversion system according to the present exemplary embodiment.

As illustrated in FIG. 32, a distance image sensor 410 includes an optical system 407, a photoelectric conversion apparatus 408, an image processing circuit 404, a monitor 405, and a memory 406. Then, the distance image sensor 410 acquires a distance image corresponding to a distance from a subject by receiving light (modulated light or pulsed light) that has been projected from a light source device 409 toward the subject and reflected from the surface of the subject.

The optical system 407 includes one or more lenses and forms an image on a light-receiving surface (a sensor unit) of the photoelectric conversion apparatus 408 by guiding image light (incident light) from the subject to the photoelectric conversion apparatus 408.

As the photoelectric conversion apparatus 408, the photoelectric conversion apparatus according to each of the above-described exemplary embodiments is applied, and a distance signal indicating the distance obtained from a received light signal output from the photoelectric conversion apparatus 408 is supplied to the image processing circuit 404.

The image processing circuit 404 performs image processing to construct a distance image based on the distance signal supplied from the photoelectric conversion apparatus 408. Then, the distance image (image data) obtained by the image processing is supplied to and displayed on the monitor 405 or is supplied to and stored (recorded) in the memory 406.

Application of the above-described photoelectric conversion apparatus to the distance image sensor 410 having the above-describe configuration leads to achievement of acquiring a more accurate distance image, for example, in accordance with the improved characteristics of pixels.

### Sixteenth Exemplary Embodiment

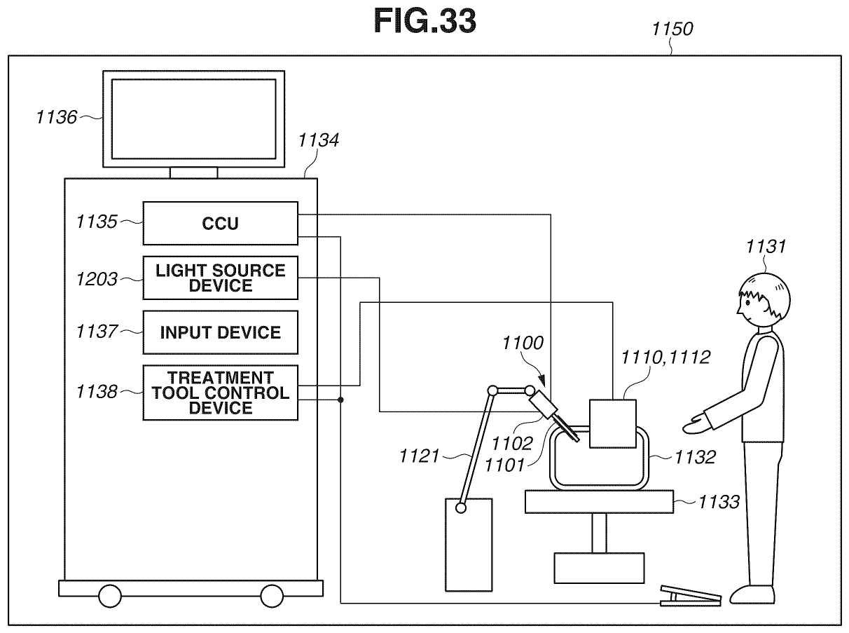

With reference to FIG. 33, a photoelectric conversion system according to a sixteenth exemplary embodiment is described. FIG. 33 is a diagram illustrating an example of the general configuration of an endoscopic operation system that is the photoelectric conversion system according to the present exemplary embodiment.

FIG. 33 illustrates the state where a user (doctor) 1131 performs a surgery on a patient 1132 on a patient bed 1133 using an endoscopic operation system 1150. As illustrated in FIG. 33, the endoscopic operation system 1150 includes an endoscope 1100, surgical tools 1110, and a cart 1134 equipped with various devices for an endoscopic operation.

The endoscope 1100 includes a lens barrel 1101 having a part to be inserted into a body cavity of a patient 1132 by a predetermined length from its front end, and a camera head 1102 connected to the base end of the lens barrel 1101. While, in the example illustrated in FIG. 28, the endoscope 1100 configured as a so-called rigid scope including the rigid lens barrel 1101, the endoscope 1100 may be configured as a so-called flexible scope including a flexible lens barrel.

An opening portion into which an objective lens is fitted is at the front end of the lens barrel 1101. A light source device 1203 is connected to the endoscope 1100. Light generated by the light source device 1203 is guided to the front end of the lens barrel 1101 by a light guide extended inside the lens barrel 1101, passes through the objective lens, and is emitted toward an observation target in the body cavity of the patient 1132. The endoscope 1100 may be a forward-viewing endoscope, or may be an oblique-viewing endoscope, or may be a side-viewing endoscope.

An optical system and a photoelectric conversion apparatus are disposed inside the camera head 1102, and reflected light (observation light) from the observation target is collected on the photoelectric conversion apparatus by the optical system. The observation light is photoelectrically converted by the photoelectric conversion apparatus, and an electric signal corresponding to the observation light, i.e., an image signal corresponding to an observation image, is generated. The photoelectric conversion apparatus according to each of the above-described exemplary embodiments can be used as the photoelectric conversion apparatus. The image signal is transmitted to a camera control unit (CCU) 1135 as RAW data.

The CCU 1135 includes a central processing unit (CPU) and a graphics processing unit (GPU), and comprehensively controls operations of the endoscope 1100 and a display device 1136. Further, the CCU 1135 receives an image signal from the camera head 1102 and performs various types of image processing for displaying an image based on the image signal, such as a development process (demosaic process), on the image signal.

Based on the control of the CCU 1135, the display device 1136 displays an image based on the image signal subjected to the image processing performed by the CCU 1135.

The light source device 1203 includes a light source, such as a light-emitting diode (LED), and supplies emission light for image capturing of an operation site to the endoscope 1100.

An input device 1137 is an input interface for an input to the endoscopic operation system 1150. A user can input various pieces of information and input an instruction to the endoscopic operation system 1150 via the input device 1137.

A treatment tool control device 1138 controls driving of energy treatment tools 1112 for cauterizing or incising tissue or sealing blood vessels.

The light source device 1203 that supplies emission light for capturing an operation site to the endoscope 1100 can include an LED, a laser light source, or a white light source configured by the combination of these, for example. In a case of a white light source including a combination of RGB laser light sources, the output intensity and an output timing of each color (each wavelength) can be controlled highly accuracy, and thus the white balance of a captured image can be adjusted in the light source device 1203.

In this case, laser light is emitted from each of the RGB laser light sources onto the observation target in a time division manner, and the driving of an imaging element of the camera head 1102 is controlled in synchronization with the emission timing of the laser light, whereby an image corresponding to each of RGB can also be captured in a time division manner. According to this method, it is possible to obtain a color image without providing color filters in the imaging element.

The driving of the light source device 1203 may be controlled in such a manner that the intensity of light to be output from the light source device 1203 is changed every predetermined time. Images are acquired in a time division manner by controlling the driving of the image element of the camera head 1102 in synchronization with the change timing of the light intensity, and the images are combined, whereby a high dynamic range image without so-called blocked-up shadows and blown-out highlights is generated.

The light source device 1203 may also be configured to supply light in a predetermined wavelength band adapted to special light observation. In the special light observation, for example, the wavelength dependence of light absorption of body tissues is utilized. Specifically, light in a narrower band than emission light (i.e., white light) in normal observation is emitted to capture an image of a predetermined tissue, such as blood vessels in a superficial layer of a mucous membrane, with high contrast. Alternatively, in the special light observation, fluorescence observation to obtain an image with fluorescent light generated by emitting excitation light may be performed. In the fluorescence observation, fluorescent light from the tissue of the body is observed by emitting excitation light onto the body tissue, or a fluorescent image is obtained by locally injecting reagent, such as indocyanine green (ICG), into a body tissue and emitting excitation light suitable for a fluorescence wavelength of the reagent onto the body tissue. The light source device 1203 can be configured to supply narrow-band light and/or excitation light adapted to such special light observation.

### Seventeenth Exemplary Embodiment

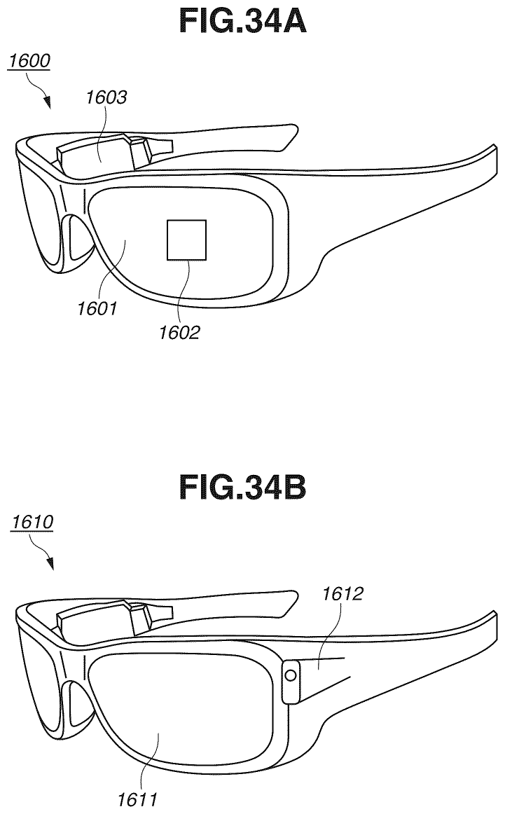

With reference to FIGS. 34A and 34B, a photoelectric conversion system according to a fifteenth exemplary embodiment is described. FIG. 34A illustrates eyeglasses 1600 (smart glasses) that are the photoelectric conversion system according to the present exemplary embodiment. The eyeglasses 1600 include a photoelectric conversion apparatus 1602. The photoelectric conversion apparatus 1602 is the photoelectric conversion apparatus described in any of the above-described exemplary embodiments. On the back surface side of a lens 1601, a display device including a light emission device, such as an organic light emitting diode (OLED) or an LED, may be disposed. The number of photoelectric conversion apparatuses 1602 may be one or plural.

In addition, a plurality of types of photoelectric conversion apparatuses 1602 may be used in combination. An arrangement position of the photoelectric conversion apparatus 1602 is not limited to the position illustrated in FIG. 34A.

The eyeglasses 1600 further include a control device 1603. The control device 1603 functions as a power source that supplies power to the photoelectric conversion apparatus 1602 and the above-described display device. The control device 1603 also controls operations of the photoelectric conversion apparatus 1602 and the display device.

In the lens 1601, an optical system for condensing light to the photoelectric conversion apparatus 1602 is formed.

FIG. 34B illustrates eyeglasses 1610 (smart glasses) as an application example. The eyeglasses 1610 include a control device 1612, and the control device 1612 is equipped with a photoelectric conversion apparatus equivalent to the photoelectric conversion apparatus 1602, and a display device. In a lens 1611, an optical system for projecting light emitted from the photoelectric conversion apparatus and the display device in the control device 1612 is formed, and an image is projected onto the lens 1611.

The control device 1612 functions as a power source that supplies power to the photoelectric conversion apparatus and the display device and controls operations of the photoelectric conversion apparatus and the display device. The control device 1612 may include a line of sight detection unit that detects a line of sight of a wearer (user). Infrared light may be used for the detection of a line of sight. An infrared light emission unit emits infrared light onto an eyeball of a user looking at a displayed image. An imaging unit including a light receiving element detects reflected light of the emitted infrared light that has been reflected from the eyeball, whereby a captured image of the eyeball is obtained. A reduction unit for reducing light from the infrared light emission unit to a display unit in a planar view is disposed so that a decline in image quality is suppressed.

A captured image of an eyeball obtained by the image capturing using infrared light is used to detect a line of sight of the user with respect to a displayed image. Any known method can be applied to the line of sight detection using a captured image of an eyeball. As an example, a line of sight detection method based on a Purkinje image obtained by reflection of irradiating light on a cornea can be used.

More specifically, a line of sight detection process based on the pupil center corneal reflection method is performed. A line of sight vector representing the direction (rotational angle) of an eyeball is calculated using the pupil center corneal reflection method, based on an image of a pupil and a Purkinje image that are included in a captured image of the eyeball, whereby a line of sight of the user is detected.

The display device of the present exemplary embodiment may include the photoelectric conversion apparatus including a light receiving element, and a displayed image on the display device may be controlled based on line of sight information on the user from the photoelectric conversion apparatus.

Specifically, in the display device, a first field of view region viewed by the user, and a second field of view region other than the first field of view region are determined based on the line of sight information. The first field of view region and the second field of view region may be determined by a control device of the display device, or the display device may receive the first field of view region and the second field of view region determined by an external control apparatus. In a display region of the display device, a display resolution of the first field of view region may be controlled to be higher than a display resolution of the second field of view region. More specifically, a resolution of the second field of view region may be set lower than a resolution of the first field of view region.

In addition, the display region includes a first display region and a second display region different from the first display region. Based on the line of sight information, a region with high priority may be determined from the first display region and the second display region. The first display region and the second display region may be determined by the control device of the display device, or the display device may receive the first display region and the second display region determined by an external control apparatus. Control may be performed in such a manner that a resolution of a region with high priority is controlled to be higher than a resolution of a region other than the region with high priority. In other words, a resolution of a region with relatively-low priority may be set to a low resolution.

Artificial intelligence (AI) may be used for determination of the first field of view region and the region with high priority. The AI may be a model configured to estimate an angle of a line of sight and a distance to a target object existing at the end of the line of sight, from an image of an eyeball by using training data including an image of the eyeball and a direction in which the eyeball in the image actually gives a gaze. An AI program may be included in the display device, the photoelectric conversion apparatus, or an external apparatus. In a case where an external apparatus includes an AI program, the AI program is transmitted to the display device via communication.

In a case where display control is performed based on line of sight detection, the present invention can be suitably applied to smart glasses further including a photoelectric conversion apparatus that captures an image of the outside. The smart glasses can display external information obtained by image capturing, in real time.

### Modified Exemplary Embodiments

The present invention is not limited to the above-described exemplary embodiments and can be modified in various ways.

For example, the exemplary embodiments of the present invention also include an example in which the configuration of a part of any of the exemplary embodiments is added to another exemplary embodiment, and an example where the configuration of a part of any of the exemplary embodiments is replaced with the configuration of a part of another exemplary embodiment.

The photoelectric conversion system illustrated in each of the seventh and thirteenth exemplary embodiments illustrates an example of a photoelectric conversion system to which the photoelectric conversion apparatus can be applied, and a photoelectric conversion system to which the photoelectric conversion apparatus according to the present invention is applicable is not limited to the configurations illustrated in FIG. 30 and FIGS. 31A and 31B. The same applies to the ToF system illustrated in the fifteenth exemplary embodiment, the endoscope illustrated in the sixteenth exemplary embodiment, and the smart glasses illustrated in the seventeenth exemplary embodiment.

The above-described exemplary embodiments are merely examples of exemplary embodiments for carrying out the present invention, and the technical scope of the present invention should not be interpreted in a limited manner by the exemplary embodiments. That is, the present invention can be implemented in various forms without departing from the technical idea or the main features thereof.

The present invention is not limited to the above-described exemplary embodiments, and various modifications and variations can be made without departing from the spirit and scope of the present invention. Accordingly, the following claims are appended to disclose the scope of the present invention.

According to the present invention, crosstalk in a photoelectric conversion apparatus that uses an avalanche photodiode is reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A photoelectric conversion apparatus comprising:
a plurality of avalanche diodes disposed in a semiconductor layer including a first surface and a second surface facing the first surface; and
a first wiring structure in contact with the second surface,
each of the plurality of avalanche diodes including
a first semiconductor region of a first conductivity type disposed at a first depth, and
a second semiconductor region of a second conductivity type disposed at a second depth deeper than the first depth relative to the second surface,
wherein a first pad configured to apply a first voltage to the photoelectric conversion apparatus is disposed in the first wiring structure,
wherein the semiconductor layer includes a plurality of uneven structures disposed in the first surface, and
wherein an effective pitch of the plurality of uneven structures is smaller than hc/Eₐ where h is a Planck constant [J·s], c is a speed of light [m/s], and Eₐ is a band gap [J] of a substrate.

2. The photoelectric conversion apparatus according to claim 1,
wherein the plurality of uneven structures is in a form of a trench structure, and
wherein a width of the trench structure is smaller than hc/2Eₐ where h is the Planck constant [J·s], c is the speed of light [m/s], and Eₐ is the band gap [J] of the substrate.

3. A photoelectric conversion apparatus comprising:
a plurality of avalanche diodes disposed in a semiconductor layer including a first surface and a second surface facing the first surface; and
a first wiring structure in contact with the second surface,
each of the plurality of avalanche diodes including
a first semiconductor region of a first conductivity type disposed at a first depth, and
a second semiconductor region of a second conductivity type disposed at a second depth deeper than the first depth relative to the second surface,
wherein a first pad configured to apply a first voltage to the photoelectric conversion apparatus is disposed in the first wiring structure,
wherein the semiconductor layer includes a plurality of uneven structures disposed in the first surface, and
wherein an effective pitch of the plurality of uneven structures is smaller than 1.1 μm.

4. The photoelectric conversion apparatus according to claim 3,
wherein the plurality of uneven structures is in a form of a trench structure, and
wherein a width of the trench structure is smaller than 0.55 μm.

5. The photoelectric conversion apparatus according to claim 1, wherein each of the plurality of avalanche diodes includes a third semiconductor region of the second conductivity type disposed at a third depth deeper than the second depth relative to the second surface.

6. The photoelectric conversion apparatus according to claim 5,
wherein each of the plurality of avalanche diodes includes a fourth semiconductor region of the first conductivity type between the second semiconductor region and the third semiconductor region, and
wherein an impurity concentration of the first conductivity type of the fourth semiconductor region is lower than an impurity concentration of the first conductivity type of the first semiconductor region.

7. The photoelectric conversion apparatus according to claim 6, wherein in a planar view in a direction perpendicular to the first surface, an area of a portion of the plurality of uneven structures that overlaps the fourth semiconductor region is greater than an area of a portion of the plurality of uneven structures that does not overlap the fourth semiconductor region.

8. The photoelectric conversion apparatus according to claim 1,
wherein each of the plurality of avalanche diodes includes a fifth semiconductor region disposed at the first depth and surrounding the first semiconductor region in a planar view in a direction perpendicular to the first surface, and
wherein an impurity concentration of the fifth semiconductor region is lower than an impurity concentration of the first semiconductor region.

9. The photoelectric conversion apparatus according to claim 8, wherein a potential difference between the first semiconductor region and the second semiconductor region is greater than a potential difference between the second semiconductor region and the fifth semiconductor region.

10. The photoelectric conversion apparatus according to claim 1, wherein in a planar view in a direction perpendicular to the first surface, a multiplication region formed between the first semiconductor region and the second semiconductor region is included in the plurality of uneven structures.

11. The photoelectric conversion apparatus according to claim 10, wherein in the planar view in the direction perpendicular to the first surface, a position of a center of gravity of the plurality of uneven structures is included in the multiplication region.

12. The photoelectric conversion apparatus according to claim 10,
wherein the plurality of avalanche diodes includes a first avalanche diode and a second avalanche diode adjacent to the first avalanche diode, and
wherein a pixel separation portion is disposed between the first avalanche diode and the second avalanche diode.

13. The photoelectric conversion apparatus according to claim 12,
wherein the plurality of avalanche diodes includes a third avalanche diode adjacent to the second avalanche diode,
wherein a first pixel separation portion is disposed between the first avalanche diode and the second avalanche diode,
wherein a second pixel separation portion is disposed between the second avalanche diode and the third avalanche diode, and
wherein the second semiconductor region in the second avalanche diode extends from the first pixel separation portion to the second pixel separation portion in a cross section perpendicular to the first surface.

14. The photoelectric conversion apparatus according to claim 13, wherein a distance d from the first surface to the multiplication region satisfies
L√2/4<d<L×√2
where in each of the plurality of avalanche diodes, a distance from the pixel separation portion to a pixel separation portion at a closest position is L.

15. The photoelectric conversion apparatus according to claim 10, further comprising
an antireflection film stacked on the first surface of the plurality of uneven structures,
wherein a refractive index of the antireflection film is lower than an effective refractive index of a region that overlaps the multiplication region in the planar view in the direction perpendicular to the first surface and is between a surface on the second surface side of the plurality of uneven structures and the first surface.

16. The photoelectric conversion apparatus according to claim 1, wherein in a planar view in a direction perpendicular to the first surface, the plurality of uneven structures includes a T-shaped trench structure.

17. The photoelectric conversion apparatus according to claim 1, wherein in a planar view in a direction perpendicular to the first surface, the plurality of uneven structures includes a trench structure configured in a non-cyclic manner.

18. The photoelectric conversion apparatus according to claim 1, wherein a distribution of density of the plurality of uneven structures is not uniform in the first surface.

19. The photoelectric conversion apparatus according to claim 18, wherein the density of the plurality of uneven structures in a center portion of the avalanche diode is higher than density of the uneven structures in an outer edge portion of the avalanche diode.

20. The photoelectric conversion apparatus according to claim 1, wherein the plurality of uneven structures includes a first uneven structure and a second uneven structure, and a depth from the first surface to a bottom portion of the first uneven structure and a depth from the first surface to a bottom portion of the second uneven structure are different from each other.

21. The photoelectric conversion apparatus according to claim 20, wherein the depth from the first surface to the bottom portion of the first uneven structure disposed in a center portion of the avalanche diode is deeper than the depth from the first surface to the bottom portion of the second uneven structure disposed in an outer edge portion of the avalanche diode.

22. The photoelectric conversion apparatus according to claim 20, wherein the depth from the first surface to the bottom portion in a portion where a recessed portion extending in a first direction and a recessed portion extending in a second direction intersect each other in the plurality of uneven structures is deeper than the depth from the first surface to the bottom portion in the recessed portion extending in the second direction that does not intersect the recessed portion extending in the first direction.

23. The photoelectric conversion apparatus according to claim 22, wherein the bottom portion in the portion where the recessed portions intersect each other is at a position closer to the first surface than half a distance between the first surface and the second surface.

24. The photoelectric conversion apparatus according to claim 1, wherein the plurality of uneven structures includes a plurality of regions independent of each other in a planar view in a direction perpendicular to the first surface.

25. The photoelectric conversion apparatus according to claim 1, wherein the plurality of uneven structures includes a gap.

26. The photoelectric conversion apparatus according to claim 1, wherein the plurality of uneven structures includes a pinning film.

27. The photoelectric conversion apparatus according to claim 1, wherein the effective pitch of the plurality of uneven structures is smaller than a wavelength at which a light absorption length of the semiconductor layer is equal to a distance from the first surface to between the first semiconductor region and the second semiconductor region.

28. The photoelectric conversion apparatus according to claim 1, further comprising
a second wiring structure in contact with the first wiring structure,
wherein a second pad configured to apply a second voltage to the photoelectric conversion apparatus is disposed in the second wiring structure.

29. The photoelectric conversion apparatus according to claim 28, wherein the second wiring structure includes a plurality of wiring layers, and the second pad is disposed in one of the plurality of wiring layers.

30. The photoelectric conversion apparatus according to claim 1, wherein the first wiring structure includes a plurality of wiring layers, and the first pad is disposed in one of the plurality of wiring layers.

31. The photoelectric conversion apparatus according to claim 30,
wherein the plurality of wiring layers included in the first wiring structure includes a wire containing copper as a main component, and
wherein a main component of the first pad is aluminum.

32. A photoelectric conversion apparatus comprising:
a plurality of avalanche diodes disposed in a semiconductor layer including a first surface and a second surface facing the first surface;
a first wiring structure in contact with the second surface; and
a second wiring structure in contact with the first wiring structure,
each of the plurality of avalanche diodes including
a first semiconductor region of a first conductivity type disposed at a first depth, and
a second semiconductor region of a second conductivity type disposed at a second depth deeper than the first depth relative to the second surface,
wherein a first pad configured to apply a first voltage to the photoelectric conversion apparatus is disposed in the second wiring structure,
wherein the semiconductor layer includes a plurality of uneven structures disposed in the first surface, and
wherein an effective pitch of the plurality of uneven structures is smaller than hc/Eₐ where h is a Planck constant [J·s], c is a speed of light [m/s], and Eₐ is a band gap [J] of a substrate.

33. A photoelectric conversion apparatus comprising:
a plurality of avalanche diodes disposed in a semiconductor layer including a first surface and a second surface facing the first surface;
a first wiring structure in contact with the second surface; and
a second wiring structure in contact with the first wiring structure,
each of the plurality of avalanche diodes including
a first semiconductor region of a first conductivity type disposed at a first depth, and
a second semiconductor region of a second conductivity type disposed at a second depth deeper than the first depth relative to the second surface,
wherein a first pad configured to apply a first voltage to the photoelectric conversion apparatus is disposed in the second wiring structure,
wherein the semiconductor layer includes a plurality of uneven structures disposed in the first surface, and
wherein an effective pitch of the plurality of uneven structures is smaller than 1.1 μm.

34. The photoelectric conversion apparatus according to claim 32, wherein a second pad configured to apply a second voltage is disposed in the second wiring structure.

35. A photoelectric conversion system comprising:
the photoelectric conversion apparatus according to claim 1; and
a signal processing unit configured to generate an image using a signal output from the photoelectric conversion apparatus.

36. A movable body comprising:
the photoelectric conversion apparatus according to claim 1; and
a control unit configured to control a movement of the movable body by using a signal output from the photoelectric conversion apparatus.
